(19) United States
(12) Patent Application Publication
(10) Pub. No.: US 2025/0227865 A1
(43) Pub. Date: Jul. 10, 2025

(54) ELECTRONIC DEVICE COMPRISING DISPLAY SUPPORT STRUCTURE

(71) Applicant: Samsung Electronics Co., Ltd., Suwon-si (KR)

(72) Inventors: Junyoung CHOI, Suwon-si (KR); Youngmin KANG, Suwon-si (KR); Moonchul SHIN, Suwon-si (KR); Jaeuk AHN, Suwon-si (KR); Yeonggyu YOON, Suwon-si (KR); Joongyeon CHO, Suwon-si (KR); Sukdong KIM, Suwon-si (KR); Soohyun SEO, Suwon-si (KR); Byounguk YOON, Suwon-si (KR)

(21) Appl. No.: 19/092,590

(22) Filed: Mar. 27, 2025

Related U.S. Application Data
(63) Continuation of application No. PCT/KR2023/014576, filed on Sep. 22, 2023.

(30) Foreign Application Priority Data
Oct. 4, 2022 (KR) 10-2022-0126635
Oct. 28, 2022 (KR) 10-2022-0141870

(51) Int. Cl. H05K 5/02

(52) U.S. Cl. CPC H05K 5/0217

(57) ABSTRACT

An example electronic device may include a first housing, a second housing coupled to the first housing, and a display including a first area disposed on the second housing and a second area extending from the first area. The electronic device may further include a first driver for moving the second housing with respect to the first housing in a first direction or a second direction opposite to the first direction; and a second driver for moving the second area. The second driver may include a belt including a first connector coupled to one edge of the second area, perpendicular to the first direction and spaced apart from the first area, and a second connector coupled to the first housing; and at least one roller arranged with respect to the belt.

### CROSS-REFERENCE TO RELATED APPLICATIONS

This application is a continuation of International Application No. PCT/KR2023/014576, designating the United States, filed on Sep. 22, 2023, in the Korean Intellectual Property Receiving Office, and claiming priority to Korean Patent Application Nos. 10-2022-0126635 filed on Oct. 4, 2022 and 10-2022-0141870 filed on Oct. 28, 2022, in the Korean Intellectual Property Office, the disclosures of each of which are incorporated by reference herein in their entireties.

### BACKGROUND

### Field

The disclosure relates to an electronic device including a display support structure.

### Description of Related Art

In order for a user to easily carry an electronic device, the electronic device may be miniaturized. Despite the miniaturization of the electronic device, there is an increasing need for electronic devices in which a size of a display for displaying contents may be changed such that the user may be provided with various contents through the electronic device. For example, an electronic device may include a flexible display in which the size of the display visually exposed to the outside of the electronic device may be changed.

### SUMMARY

According to an embodiment, an electronic device may include a first housing, a second housing movably coupled to the first housing, and a display including a first region disposed on the second housing, and a second region extending from the first region. The electronic device may further include a first driving part (driver), including a motor, configured to move the first housing in a first direction or a second direction opposite to the first direction with respect to the second housing, and coupled to the second housing, and a second driving part (driver), coupled to the first housing to move with respect to the second housing in accordance with a movement of the first housing to move with respect to the second housing, and configured to move the second region of the display in the first direction or the second direction. The second driving part may include a belt including a first connecting portion (connector) coupled to a periphery of the second region of the display spaced apart from the first region of the display, and a second connecting portion (connector) coupled to the second housing and at least one roller arranged with respect to the belt. The at least one roller may be configured to rotate with respect to the first housing by the second driving part configured to move with respect to the first housing. The first connecting portion of the belt may be configured to move by a rotation of the at least one roller in a first rotational direction with respect to the second connecting portion of the belt, the second connecting portion being coupled to the second housing independently of the rotation of the at least one roller.

According to an embodiment, an electronic device may include a first housing, a second housing movably coupled to the first housing, and a display including a first region disposed on the second housing, and a second region extending from the first region. The electronic device may further include a first driving part (driver), including a motor, configured to move the second housing in a first direction or a second direction opposite to the first direction with respect to the first housing and coupled to the second housing, and a second driving part (driver), coupled to the first housing to move with respect to the second housing in accordance with a movement of the first housing to move with respect to the second housing and configured to move the second region of the display in the first direction or the second direction opposite to the first direction. The second driving part may include a belt including a first connecting portion (connector) coupled to a periphery of the second region of the display spaced apart from the first region of the display, and a second connecting portion (connector) coupled to the second housing and at least one roller in contact with the belt. The at least one roller may be configured to rotate in a first rotational direction in accordance with the movement of at least one roller in the first direction with respect to the second housing, or rotate in a second rotational direction opposite to the first rotational direction in accordance with the movement of at least one roller in the second direction with respect to the second housing by the second driving part moving with respect to the second housing. The first connecting portion of the belt may be configured to move in the first direction with respect to the second connecting portion of the belt by a rotation of the at least one roller in the first rotational direction or move in the second direction with respect to the second connecting portion of the belt by the rotation of the at least one roller in the second rotational direction, the second connecting portion being coupled to the second housing independently of the rotation of the at least one roller. The second region of the display may be configured to be exposed to an outside of the second housing based on the movement of the first connecting portion of the belt in the first direction or be rolled into the second housing based on the movement of the first connecting portion of the belt in the second direction.

### BRIEF DESCRIPTION OF THE DRAWINGS

FIG. 1 is a block diagram of an example electronic device in a network environment according to various embodiments;

FIG. 2A is a top plan view of an example electronic device in a first state according to various embodiments;

FIG. 2B is a bottom view of an example electronic device in a first state according to various embodiments;

FIG. 2C is a plan view of an example electronic device in a second state according to various embodiments;

FIG. 2D is a bottom view of an example electronic device in a second state according to various embodiments;

FIGS. 3A and 3B are exploded perspective views of an example electronic device according to various embodiments;

FIG. 4A is a cross-sectional view of an example electronic device in a first state according to various embodiments;

FIG. 4B is a cross-sectional view of an example electronic device in a second state according to various embodiments;

FIG. 5A is a perspective view of a driving part of an example exemplary electronic device according to various embodiments;

FIG. 5B illustrates a portion of an example electronic device according to various embodiments;

FIGS. 6A and 6B are partial cross-sectional views of an example electronic device according to various embodiments;

FIG. 7 illustrates a portion of an example electronic device according to various embodiments;

FIG. 8A illustrates a portion of an example electronic device according to various embodiments;

FIG. 8B is a partial cross-sectional view of an example electronic device according to various embodiments; and

FIG. 9 illustrates a portion of an example electronic device according to various embodiments.

### DETAILED DESCRIPTION

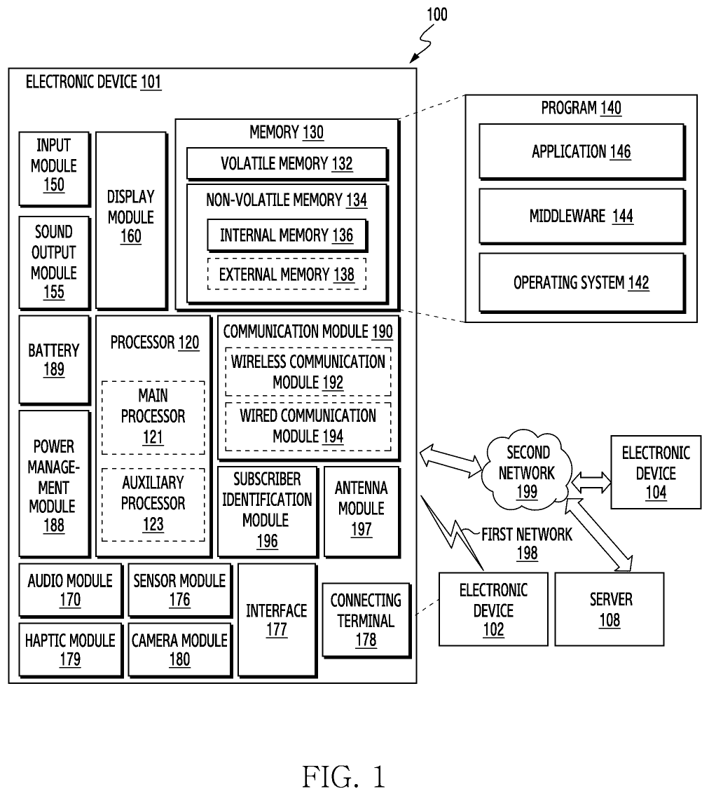

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 (including, e.g., processing circuitry) may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, the various processors may operate individually or collectively to perform operations or functions. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 (including, e.g., input circuitry) may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 (including, e.g., sound output circuitry) may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of, the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 (including, e.g., audio circuitry) may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 (including, e.g., interface circuitry) may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 (including, e.g., haptic circuitry) may convert an electrical signal into a mechanical stimulus (e.g., a vibration or a movement) or electrical stimulus which may be recognized by a user via tactile sensation or kinesthetic sensation. According to an embodiment, the haptic module 179 may include, for example, a motor, a piezoelectric element, or an electric stimulator.

The camera module 180 (including, e.g., a camera) may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 (including, e.g., communication circuitry) may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors (each including, e.g., communication processing circuitry) that are operable independently from the processor 120 (e.g., the application processor (AP)) and supports a direct (e.g., wired) communication or a wireless communication. According to an embodiment, the communication module 190 may include a wireless communication module 192 (including, e.g., wireless communication circuitry) (e.g., a cellular communication module, a short-range wireless communication module, or a global navigation satellite system (GNSS) communication module) or a wired communication module 194 (including, e.g., wired communication circuitry) (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type from, the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

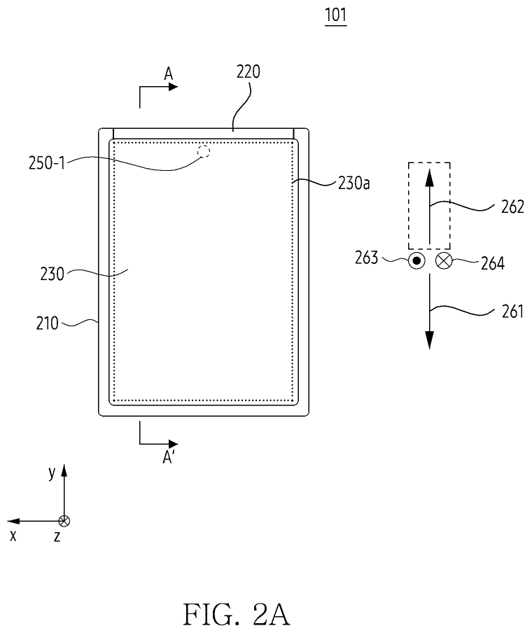

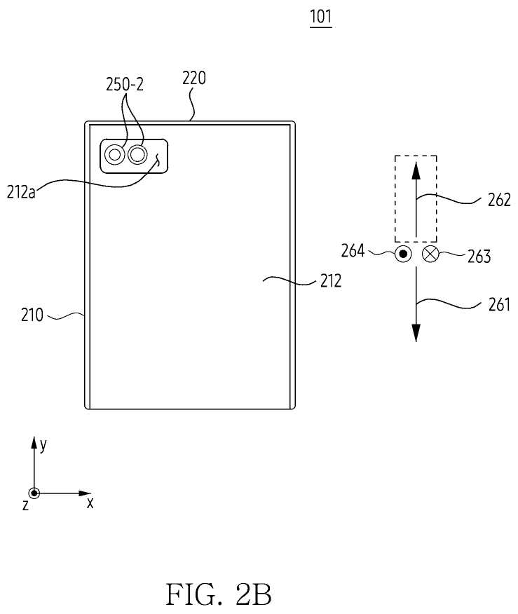

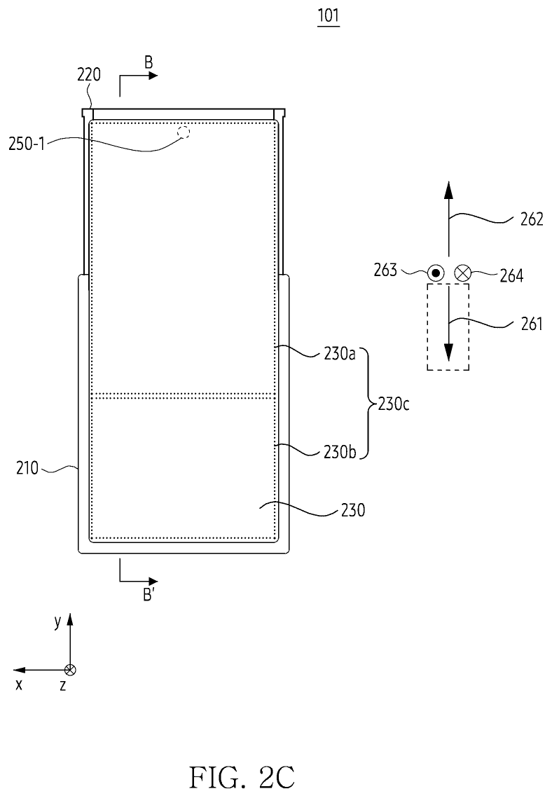

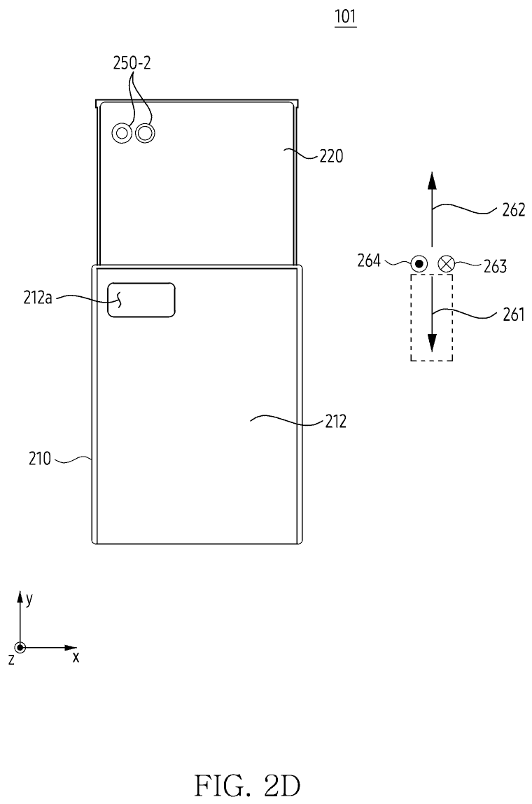

For example, a display of a display module 160 may be flexible. For example, the display may include a display region exposed outside a housing of an electronic device 101 that provides at least a portion of an outer surface of the electronic device 101. For example, since the display has flexibility, at least a portion of the display may be rollable into the housing or slidable into the housing. For example, a size of the display region may be changed according to a size of the at least a portion of the display that is rolled into the housing or slid into the housing. For example, the electronic device 101 including the display may be in a plurality of states including a first state providing the display region having a first size and a second state providing the display region having a second size different from the first size. For example, the first state will be discussed with reference to FIGS. 2A and 2B.

FIG. 2A is a top plan view of an example electronic device 101 in a first state according to various embodiments.

Referring to FIG. 2A, the electronic device 101 may include a first housing 210, a second housing 220 that is movable with respect to the first housing 210 in a first direction 261 parallel to a y-axis, or a second direction 262 parallel to the y-axis and opposite to the first direction 261, and a display 230 (e.g., the display).

For example, the electronic device 101 may be in the first state. For example, in the first state, the second housing 220 may be movable with respect to the first housing 210 in the second direction 262. For example, in the first state, the second housing 220 may not be movable in the first direction 261 with respect to the first housing 210.

For example, in the first state, the display 230 may provide the display region having the smallest size. For example, in the first state, the display region may correspond to a first region 230a. For example, although not illustrated in FIG. 2A, in the first state, a region (e.g., a second region 230b of FIG. 2C) of the display 230 different from the first region 230a, which is the display region, may be included in the first housing 210. For example, in the first state, the region may be covered by the first housing 210. For example, in the first state, the region may be rollable into the first housing 210. For example, in the first state, the first region 230a may include a planar portion, unlike the region including a curved portion. However, the disclosure is not limited in this respect. For example, in the first state, the first region 230a may include a curved portion that extends from the planar portion and is positioned in an edge portion.

For example, the first state may be referred to as a slide-in state or a closed state in terms of at least a portion of the second housing 220 being positioned in the first housing 210. For example, the first state may be referred to as a reduced state, in terms of providing the display region having the smallest size. However, the disclosure is not limited in this respect.

For example, the first housing 210 may include a first image sensor 250-1 that is visually exposed through a portion of the first region 230a and faces a third direction 263 parallel to a z-axis, in a camera module 180. For example, the camera module 180 may be disposed to perform its function without being visually exposed through a portion of the first region 230a in an internal space of an electronic device. For example, although not illustrated in FIG. 2A, the second housing 220 may include one or more second image sensors that is exposed through a portion of the second housing 220, and face in a fourth direction 264 parallel to the z-axis and opposite to the third direction 263, in the camera module 180. For example, the one or more second image sensors will be described with reference to FIG. 2B.

FIG. 2B is a bottom view of an example electronic device in a first state according to various embodiments.

Referring to FIG. 2B, in the first state, one or more second image sensors 250-2 disposed in the second housing 220 may be positioned within a structure disposed in the first housing 210 for the one or more second image sensors 250-2. For example, in the first state, light from the outside of the electronic device 101 may be received in the one or more second image sensors 250-2 through the structure. For example, since the one or more second image sensors 250-2 is positioned within the structure in the first state, the one or more second image sensors 250-2 may be exposed through the structure in the first state. For example, the structure may be variously implemented. For example, the structure may be an opening or a notch. For example, the structure may be an opening 212a in a plate 212 of the first housing 210 surrounding at least a portion of the second housing 220. However, the disclosure is not limited in this respect. For example, in the first state, the one or more second image sensors 250-2 included in the second housing 220 may be covered by the plate 212 of the first housing 210.

Referring again to FIG. 2A, the first state may be changed to the second state.

For example, the first state (or the second state) may be changed to the second state (or the first state) through one or more intermediate states between the first state and the second state.

For example, the first state (or the second state) may be changed to the second state (or the first state) based on a predefined user input. For example, the first state (or the second state) may be changed to the second state (or the first state) in response to a user input to a physical button exposed through a portion of the first housing 210 or a portion of the second housing 220. For example, the first state (or the second state) may be changed to the second state (or the first state) in response to a touch input on an executable object displayed in the display region. For example, the first state (or the second state) may be changed to the second state (or the first state) in response to a touch input having a contact point on the display region and a pressing strength greater than or equal to a reference strength. For example, the first state (or the second state) may be changed to the second state (or the first state) in response to a voice input received through a microphone of the electronic device 101. For example, the first state (or the second state) may be changed to the second state (or the first state) in response to a force applied to the first housing 210 and/or the second housing 220 to move the second housing 220 with respect to the first housing 210. For example, the first state (or the second state) may be changed to the second state (or the first state) in response to a user input identified on an external electronic device (e.g., earbuds or a smart watch) connected to the electronic device 101. The disclosure is not limited in this respect.

The second state will be described with reference to FIGS. 2C and 2D.

FIG. 2C is a plan view of an example electronic device in a second state according to various embodiments.

Referring to FIG. 2C, the electronic device 101 may be in the second state. For example, in the second state, the second housing 220 may be movable with respect to the first housing 210 in the first direction 261. For example, in the second state, the second housing 220 may not be movable in the second direction 262 with respect to the first housing 210.

For example, in the second state, the display 230 may provide a display region having the largest size. For example, in the second state, the display region may correspond to a region 230c including the first region 230a and the second region 230b. For example, the second region 230b included in the first housing 210 in the first state may be exposed in the second state. For example, in the second state, the first region 230a may include the planar portion. However, the disclosure is not limited in this respect. For example, the first region 230a may include the curved portion that extends from the planar portion and is positioned in the edge portion. For example, in the second state, the second region 230b may include the planar portion of the planar portion and the curved portion, unlike the first region 230a in the first state. However, the disclosure is not limited in this respect. For example, the second region 230b may include the curved portion that extends from the planar portion of the second region 230b and is positioned in the edge portion.

For example, the second state may be referred to as a slide-out state or an open state in terms of at least a portion of the second housing 220 being positioned outside the first housing 210. For example, the second state may be referred to as an extended state in terms of providing the display region having the largest size. However, the disclosure is not limited in this respect.

For example, when a state of the electronic device 101 changes from the first state to the second state, the first image sensor 250-1 facing the third direction 263 may move together with the first region 230a in accordance with a movement of the second housing 220 in the second direction 262. For example, although not illustrated in FIG. 2C, when the state of the electronic device 101 changes from the first state to the second state, the one or more second image sensors 250-2 facing the fourth direction 264 may be moved in accordance with the movement of the second housing 220 in the second direction 262. For example, a relative positional relationship between the one or more second image sensors 250-2 and the structure exemplified in the description of FIG. 2B may be changed in accordance with the movement of the one or more second image sensors 250-2. For example, the change in the relative positional relationship will be described with reference to FIG. 2D.

FIG. 2D is a bottom view of an example electronic device in a second state in accordance with various embodiments.

Referring to FIG. 2D, in the second state, the one or more second image sensors 250-2 may be positioned outside the structure. For example, in the second state, the one or more second image sensors 250-2 may be positioned outside the opening 212a in the plate 212. For example, since the one or more second image sensors 250-2 is positioned outside the opening 212a in the second state, the one or more second image sensors 250-2 may be exposed in the second state. For example, since the one or more second image sensors 250-2 is positioned outside the structure in the second state, the relative positional relationship in the second state may be different from the relative positional relationship in the first state.

For example, in a case that the electronic device 101 does not include the structure, such as the opening 212a, the one or more second image sensors 250-2 in the second state may be exposed, unlike the one or more second image sensors 250-2 in the first state.

Although not illustrated in FIGS. 2A, 2B, 2C, and 2D, the electronic device 101 may be in an intermediate state between the first state and the second state. For example, a size of the display region in the intermediate state may be larger than a size of the display region in the first state and smaller than a size of the display region in the second state. For example, the display region in the intermediate state may correspond to a region including the first region 230a and a portion of the second region 230b. For example, in the intermediate state, a portion of the second region 230b is exposed, and another portion (or a remaining portion) of the second region 230b may be covered by the first housing 210 or rolled into the first housing 210. However, the disclosure is not limited in this respect.

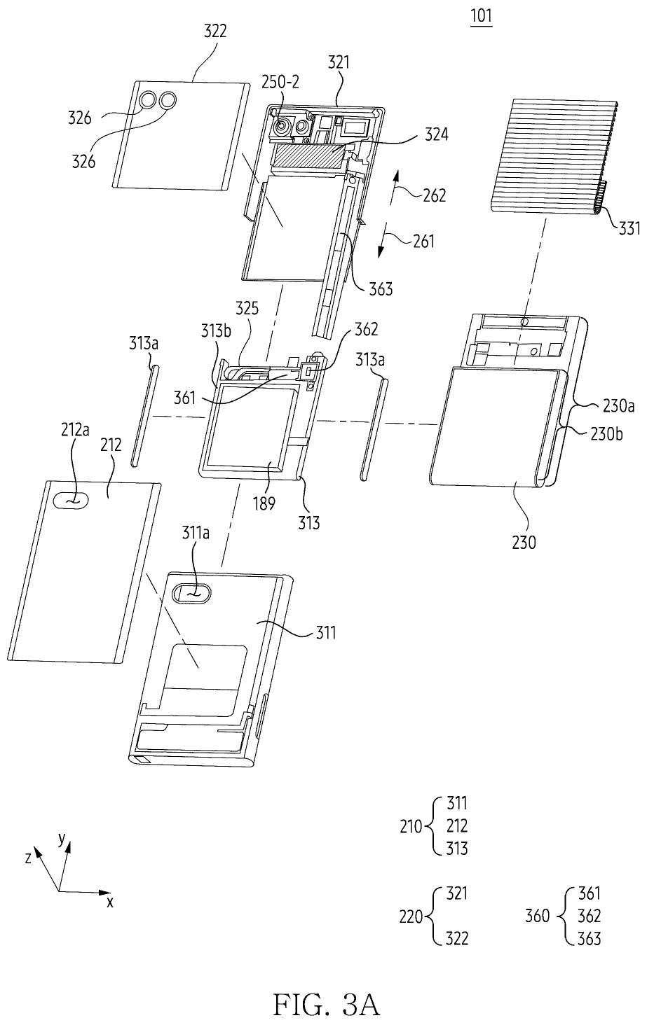

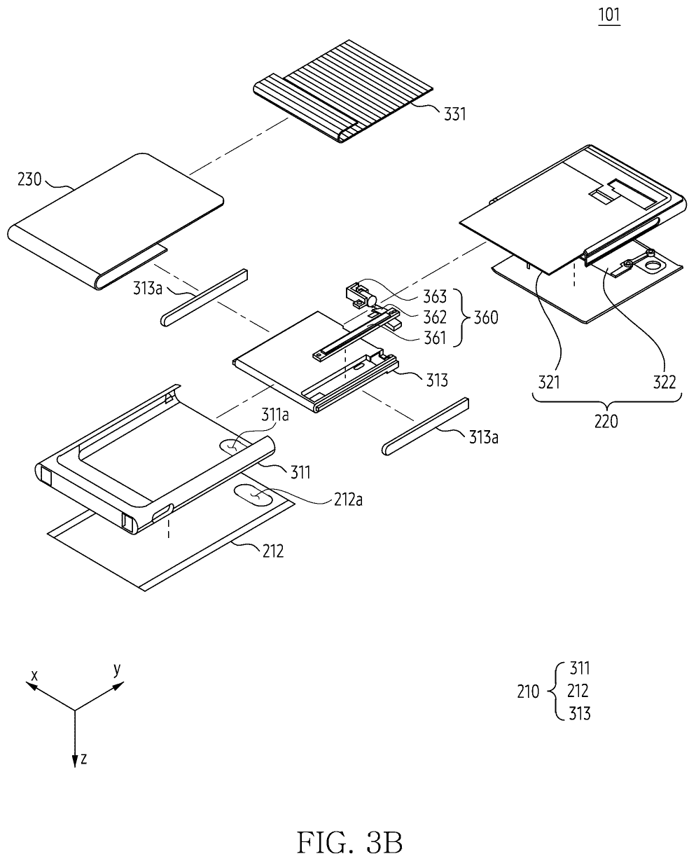

Referring again to FIG. 1, the electronic device 101 may include structures to move the second housing (e.g., the second housing 220 of FIG. 2A) of the electronic device 101 with respect to the first housing 101 (e.g., the first housing 210 of FIG. 2A) of the electronic device 101. For example, the structures will be described with reference to FIGS. 3A and 3B.

FIGS. 3A and 3B are exploded perspective views of an example electronic device according to various embodiments.

Referring to FIGS. 3A and 3B, an electronic device 101 may include a first housing 210, a second housing 220, a display 230, and a driving part (driver) 360.

For example, the first housing 210 may include a book cover 311, a plate 212, and a frame cover 313.

For example, the book cover 311 may at least partially form a lateral surface portion of an outer surface of the electronic device 101. For example, the book cover 311 may at least partially form a rear surface portion of the outer surface. For example, the book cover 311 may include an opening 311a for one or more second image sensors 250-2. For example, the book cover 311 may include a surface supporting the plate 212. For example, the book cover 311 may be coupled to the plate 212. For example, the book cover 311 may include a frame cover 313. For example, the book cover 311 may be coupled to the frame cover 313.

For example, the plate 212 may at least partially form the rear surface portion of the outer surface. For example, the plate 212 may include an opening 212a for the one or more second image sensors 250-2. For example, the plate 212 may be disposed on the surface of the book cover 311. For example, the opening 212a may be aligned with the opening 311a.

For example, the frame cover 313 may be at least partially surrounded by the book cover 311.

For example, the frame cover 313 may be at least partially surrounded by the display 230. For example, the frame cover 313 may be at least partially surrounded by the display 230, but a position of the frame cover 313 may be maintained independently of a movement of the display 230. For example, the frame cover 313 may be arranged in association with at least a portion of components of the display 230. For example, the frame cover 313 may include rails 313a that provide (or guide) a path for a movement of at least one component of the display 230.

For example, the frame cover 313 may be coupled to at least one component of the electronic device 101. For example, the frame cover 313 may support a rechargeable battery 189. For example, the battery 189 may be supported through a recess or a hole in a surface 313b of the frame cover 313. For example, the frame cover 313 may be coupled to an end of a flexible printed circuit board (FPCB) 325 on a surface of the frame cover 313. For example, although not explicitly illustrated in FIGS. 3A and 3B, another end of the FPCB 325 may be connected to a PCB 324 through at least one connector. For example, the PCB 324 may be electrically connected to another PCB (not illustrated in FIGS. 3A and 3B) that supplies power to a motor 361 through the FPCB 325.

For example, the frame cover 313 may be coupled to at least one structure of the electronic device 101 for a plurality states including a first state and a second state. For example, the frame cover 313 may fasten the motor 361 of the driving part 360.

For example, the second housing 220 may include a front cover 321 and a slide cover 322.

For example, the front cover 321 may be at least partially surrounded by the display 230. For example, unlike the frame cover 313, the front cover 321 may be coupled to at least a portion of a first region 230a of the display 230 surrounding the front cover 321, such that the display 230 is moved along the second housing 220 that moves with respect to the first housing 210.

For example, the front cover 321 may be coupled to at least one component of the electronic device 101. For example, the front cover 321 may be coupled to the printed circuit board 324 (PCB) including components of the electronic device 101. For example, the PCB 324 may include a processor 120 (not illustrated in FIGS. 3A and 3B). For example, the front cover 321 may include the one or more second image sensors 250-2.

For example, the front cover 321 may be coupled to at least one structure of the electronic device 101 for a plurality of states including the first state and the second state. For example, the front cover 321 may fasten a rack gear 363 of the driving part 360.

For example, the front cover 321 may be coupled to the slide cover 322.

For example, the slide cover 322 may be coupled to the front cover 321 to protect the at least one component of the electronic device 101 coupled in the front cover 321 and/or the at least one structure of the electronic device 101 coupled in the front cover 321. For example, the slide cover 322 may include a structure for the at least one component. For example, the slide cover 322 may include one or more openings 326 for the one or more second image sensors 250-2. For example, the one or more openings 326 may be aligned with the one or more second image sensors 250-2 disposed on the front cover 321. For example, a size of each of the one or more openings 326 may correspond to a size of each of the one or more second image sensors 250-2.

For example, the display 230 may include a support 331. For example, the support 331 may include a plurality of bars. For example, the plurality of bars may be coupled to each other.

For example, the driving part 360 may include the motor 361, a pinion gear 362, and a rack gear 363.

For example, the motor 361 may operate based on power from the battery 189. For example, the power may be provided to the motor 361 in response to the predefined user input.

For example, the pinion gear 362 may be coupled to the motor 361 through a shaft. For example, the pinion gear 362 may be rotated based on the operation of the motor 361 transmitted through the shaft.

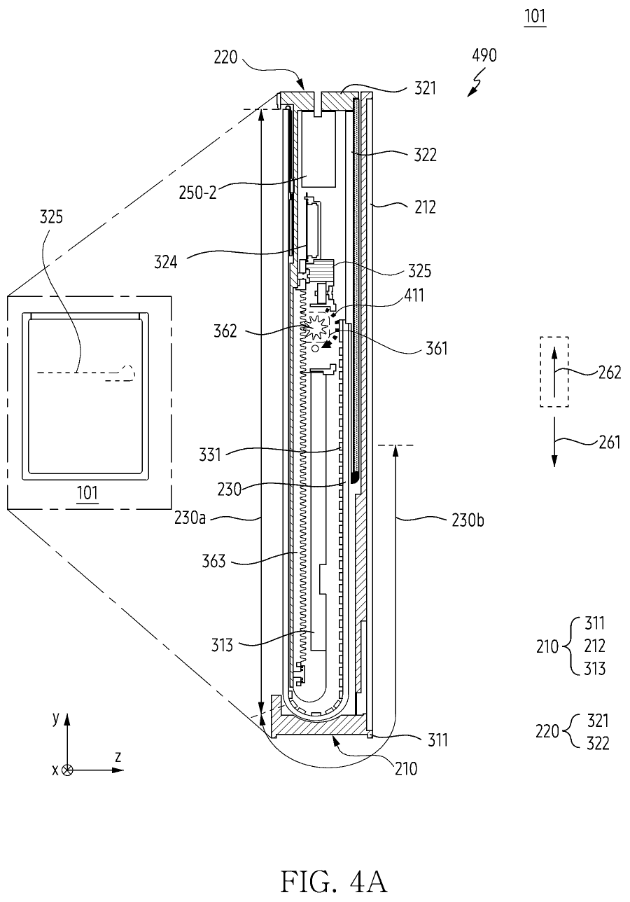

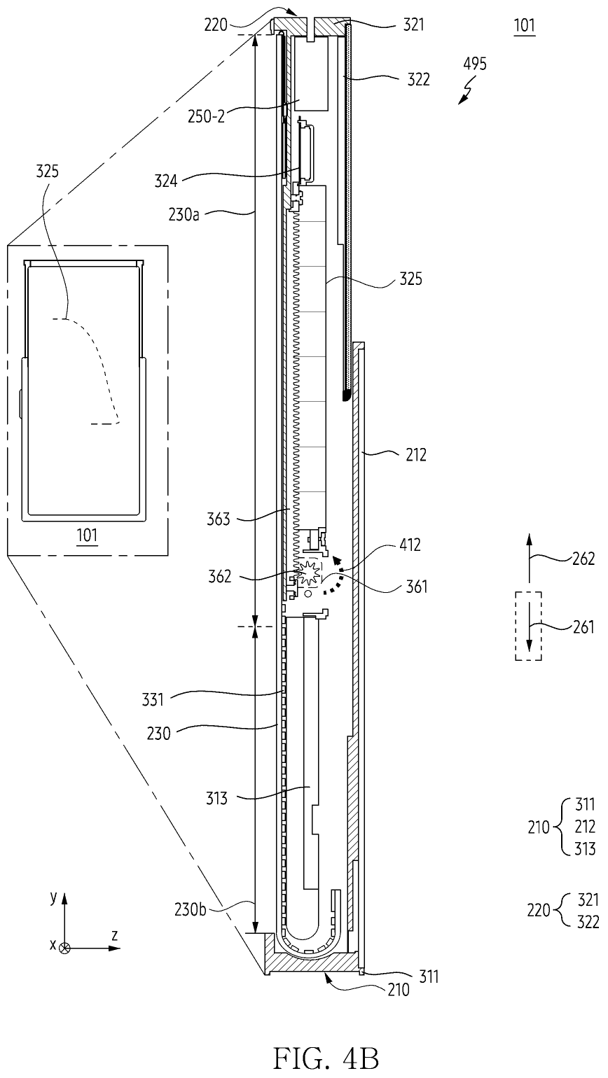

For example, the rack gear 363 may be arranged in association with the pinion gear 362. For example, teeth of the rack gear 363 may be engaged with teeth of the pinion gear 362. For example, the rack gear 363 may move in the first direction 261 or the second direction 262 according to rotation of the pinion gear 362. For example, the second housing 220 may be moved in the first direction 261 and the second direction 262 by the rack gear 363 that moves according to the rotation of the pinion gear 362 due to the operation of the motor 361. For example, the first state of the electronic device 101 may be changed to a state (e.g., the one or more intermediate states or the second state) different from the first state through the movement of the second housing 220 in the second direction 262. For example, the second state of the electronic device 101 may be changed to a state (e.g., the one or more intermediate states or the first state) different from the second state through the movement of the second housing 220 in the first direction 261. For example, the first state being changed to the second state by the driving part 360 and the second state being changed to the first state by the driving part 360 will be described with reference to FIGS. 4A and 4B.

FIG. 4A is a cross-sectional view of an example electronic device in a first state according to various embodiments. FIG. 4B is a cross-sectional view of an example electronic device in a second state according to various embodiments.

Referring to FIGS. 4A and 4B, a motor 361 may be operated based on at least in part on the predefined user input received in the first state 490. For example, a pinion gear 362 may be rotated in a first rotational direction 411 based at least in part on the operation of the motor 361. For example, a rack gear 363 may be moved in a second direction 262 based at least in part on the rotation of the pinion gear 362 in the first rotational direction 411. For example, since a front cover 321 in a second housing 220 fastens the rack gear 363, the second housing 220 may be moved in the second direction 262 based at least in part on the movement of the rack gear 363 in the second direction 262. For example, since the front cover 321 in the second housing 220 is coupled to at least a portion of a first region 230a of a display 230 and fastens the rack gear 363, the display 230 may be moved based at least in part on the movement of the rack gear 363 in the second direction 262. For example, the display 230 may be moved along rails 313a. For example, a shape of at least a portion of the plurality of bars of a support 331 of the display 230 may be changed when a state 490 changes to a state 495, which is the second state.

For example, a second region 230b of the display 230 may be moved in accordance with the movement of the display 230. For example, when the state 490 changes to the state 495 according to the predefined user input, the second region 230b may be moved through a space between a book cover 311 and a frame cover 313. For example, the second region 230b in the state 495 may be exposed, unlike the second region 230b rolled into the space in the state 490.

For example, since the front cover 321 in the second housing 220 is coupled to a PCB 324 connected to the other end of a FPCB 325 and fastens the rack gear 363, a shape of the FPCB 325 may be changed when the state 490 changes to the state 495.

The motor 361 may be operated based at least in part on the predefined user input received in the state 495. For example, the pinion gear 362 may be rotated in a second rotational direction 412 based at least in part on the operation of the motor 361. For example, the rack gear 363 may be moved in a first direction 261 based at least in part on the rotation of the pinion gear 362 in the second rotational direction 412. For example, since the front cover 321 in the second housing 220 fastens the rack gear 363, the second housing 220 may be moved in the first direction 261, based at least in part on the movement of the rack gear 363 in the first direction 261. For example, since the front cover 321 in the second housing 220 is coupled to at least a portion of the first region 230a of the display 230 and fastens the rack gear 363, the display 230 may be moved based at least in part on the movement of the rack gear 363 in the first direction 261. For example, the display 230 may be moved along the rails 313a. For example, the shape of the at least a portion of the plurality of bars of the support 331 of the display 230 may be changed when the state 495 changes to the state 490.

For example, the second region 230b of the display 230 may be moved in accordance with the movement of the display 230. For example, when the state 495 changes to the state 490 according to the predefined user input, the second region 230b may be moved through the space between the book cover 311 and the frame cover 313. For example, the second region 230b in the state 490 may be rolled into the space, unlike the second region 230b exposed in the state 495.

For example, since the front cover 321 in the second housing 220 is coupled to the PCB 324 connected to the other end of the FPCB 325 and fastens the rack gear 363, the shape of the FPCB 325 may be changed when the state 495 changes to the state 490.

FIGS. 2A, 2B, 3A, 3B, 4A, and 4B illustrate an electronic device 101 in which height of the display region is changed and width of the display region is maintained, when the first state (or the second state) changes to the second state (or the first state) in a portrait mode, but this is for convenience of description. For example, when the first state (or the second state) changes to the second state (or the first state) in the portrait mode, the electronic device 101 may be implemented such that the height of the display region is maintained and the width of the display region is changed.

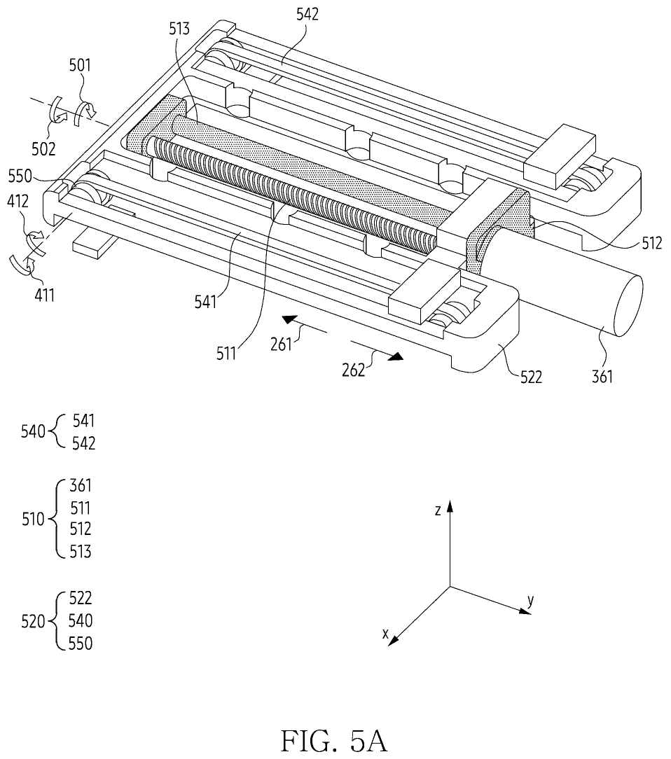

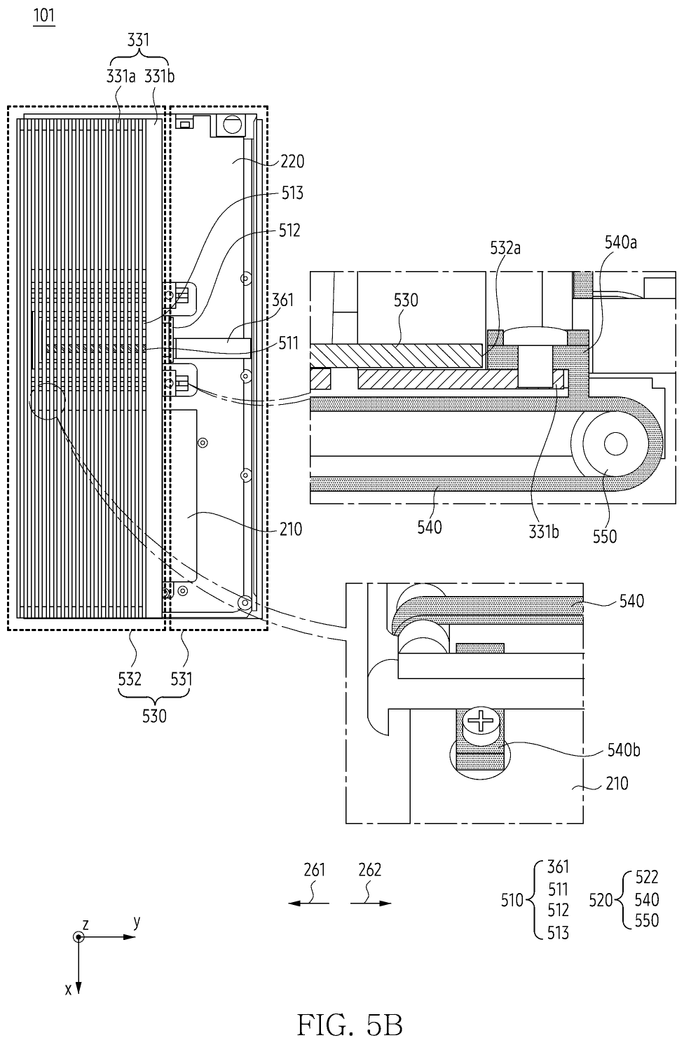

FIG. 5A is a perspective view of a driving part (driver) of an example electronic device according to various embodiments. FIG. 5B illustrates a portion of an example electronic device according to various embodiments.

Referring to FIGS. 5A and 5B, an electronic device 101 may include a first housing 210, a second housing 220, a flexible display 530 (e.g., the display 230 of FIG. 2A), a first driving part (driver) 510 (e.g., the driving part 360 of FIG. 3B), and a second driving part (driver) 520.

According to an embodiment, the second housing 220 may be coupled to the first housing 210. The first housing 210 may be movable in a first direction 261 parallel to a y-axis or a second direction 262 parallel to the y-axis and opposite to the first direction 261 with respect to the second housing 220. For example, the first housing 210 may be slidable in the first direction 261 or the second direction 262 opposite to the first direction 261 with respect to the second housing 220. For example, at least a portion of the first housing 210 may be covered by the second housing 220 in a first state. The first housing 210 may move in the first direction 261 with respect to the second housing 220 while changing from the first state to a second state. In the second state, the at least a portion of the first housing 210 may be exposed to the outside. The first housing 210 may move in the second direction 262 opposite to the first direction 261 with respect to the second housing 220 while changing from the second state to the first state.

According to an embodiment, the flexible display 530 may include a first region 531 (e.g., the first region 230a of FIG. 2A) and a second region (e.g., the second region 230b of FIG. 2C) extending from the first region 531. The first region 531 may be disposed on the second housing 220. The second region 532 may be a deformable region.

For example, the first region 531 may be disposed on the second housing 220. The first region 531 may be visually exposed to the outside. In the first state, the second region 532 may be disposed in the second housing 220. While changing from the first state to the second state, since the first housing 210 moves in the first direction 261 with respect to the second housing 220, the second region 532 disposed in the electronic device 101 in the first state may move in the first direction 261 along the first housing 210. Since the second region 532 extends from the first region 531 disposed on the second housing 220, the second region 532 may be visually exposed to the outside by moving along the first housing 210 moving with respect to the second housing 220. While changing from the first state to the second state, a visually exposed region of the flexible display 530 may increase by the visually exposed second region 532.

For example, in the second state, the second region 532 may be visually exposed to the outside. While changing from the second state to the first state, since the first housing 210 moves in the second direction 262 opposite to the first direction 261 with respect to the second housing 220, the second region 532 may move in the second direction 262 along the first housing 210. Since the second region 532 extends from the first region 531 disposed on the second housing 220, the second region 532 may move inside the second housing 220 by moving along the first housing 210. While changing from the second state to the first state, the visually exposed region of the flexible display 530 may be reduced, by the second region 532 moving inside the second housing 220.

For example, although not illustrated, a portion of the second region 532 may be visually exposed to the outside, in an intermediate state between the first state and the second state. A remainder of the second region 532 may be disposed in the second housing 220. The second region 532 may be configured to provide a plurality of states by being deformable such that the second region 532 is rolled into the second housing 220 or exposed to the outside of the electronic device 101.

The first state may be referred to as a slide-in state or a closed state in which the second region 532 is rolled into the second housing 220. The second state may be referred to as a slide-out state or an open state in which the second region 532 is exposed to the outside.

According to an embodiment, the first driving part 510 may include a motor 361. The first driving part 510 may move the first housing 210 in the first direction 261 or the second direction 262 opposite to the first direction 261 with respect to the second housing 220. The first driving part 510 may be coupled to the second housing 220. In this disclosure, an element being coupled to another element does not limit an arrangement relationship between two components because it may refer to the two components being in contact with each other and being directly coupled, or a separate component existing between the two components and the two components being indirectly coupled.

For example, the first housing 210 may be movable with respect to the first driving part 510 coupled to the second housing 220. For example, the first driving part 510 may be configured to move the first housing 210 in the first direction 261 or the second direction 262 opposite to the first direction 261 with respect to the second housing 220 by driving the motor 361 of the first driving part 510.

According to an embodiment, the second driving part 520 may be coupled to the first housing 210 to move with respect to the second housing 220 in accordance with a movement of the first housing 210 moving with respect to the second housing 220. The second driving part 520 may move the second region 532 of the flexible display 530 in the first direction 261 or in the second direction 262 opposite to the first direction 261.

For example, the second driving part 520 may move in the first direction 261 along the first housing 210 that moves in the first direction 261 with respect to the second housing 220 by the first driving part 510. The second driving part 520 may move in the second direction 262 along the first housing 210 that moves in the second direction 262 opposite to the first direction 261 with respect to the second housing 220 by the first driving part 510.

For example, the second driving part 520 may transmit a force to the second region 532 such that the second region 532 in the electronic device 101 is moved in the first direction 261 based on a movement in the first direction 261 along the first housing 210. The second driving part 520 may transmit a force to the second region 532 such that the second region 532 in the electronic device 101 is moved in the second direction 262 based on a movement in the second direction 262 opposite to the first direction 261 along the first housing 210.

For example, the second driving part 520 may be linked to the first driving part 510. The second driving part 520 may be operated based on an operation of the first driving part 510. The second driving part 520 may be configured to transmit a driving force to the flexible display 530 based on the driving force received from the first driving part 510. The second driving part 520 may be moved along the first housing 210 that is moved by the motor 361 of the first driving part 510. The second driving part 520 may transmit a force to the second region 532 such that the second region 532 moves based on the movement along the first housing 210.

According to an embodiment, the second driving part 520 may include a belt 540. The belt 540 may include a first connecting portion 540a and a second connecting portion 540b. The first connecting portion 540a may be coupled to a periphery 532a of the second region 532 spaced apart from the first region 531. The second connecting portion 540b may be coupled to the second housing 220.

For example, the periphery 532a of the second region 532 may be disposed in the electronic device 101. For example, as the second driving part 520 moves with respect to the second housing 220, at least a portion of the belt 540 may be configured to move with respect to the second housing 220 along the second driving part 520. For example, the at least a portion of the belt 540 may operate to move the second region 532 disposed in the electronic device 101, in the second driving part 520 that moves along the first housing 210. The belt 540 may be configured to transmit a driving force to the second region 532 of the flexible display 530 based on the driving force transmitted from the first driving part 510 to the second driving part 520.

For example, the first connecting portion 540a of the belt 540 may be fastened at the periphery 532a of the second region 532. For example, the first connecting portion 540a of the belt 540 may be attached to the periphery 532a of the second region 532. For example, the first connecting portion 540a of the belt 540 may be connected to the periphery 532a of the second region 532. For example, the first connecting portion 540a of the belt 540 may be coupled to at least one component (e.g., a support 331) of the electronic device 101 coupled to the periphery 532a of the second region 532. For example, the first connecting portion 540a of the belt 540 may move along the second driving part 520 that moves with respect to the second housing 220. For example, the first connecting portion 540a of the belt 540 may be moved by the belt 540 operating in the second driving part 520 that moves along the first housing 210. As the first connecting portion 540a of the belt 540 is coupled to the periphery 532a of the second region 532, the first connecting portion 540a may be configured to move the second region 532 in the electronic device 101, by transmitting the driving force to the periphery 532a, based on a movement of the second driving part 520 and/or driving of the belt 540.

For example, the second connecting portion 540b of the belt 540 may be coupled to the second housing 220 independently of the movement of the first housing 210 in the first direction 261 or the second direction 262 opposite to the first direction 261 with respect to the second housing 220. As the second connecting portion 540b is coupled to the second housing 220, the second connecting portion 540b may be configured to operate the belt 540 in the second driving part 520 by the second driving part 520 that moves along the first housing 210.

For example, the belt 540 may have a shape of a closed curve connecting the first connecting portion 540a and the second connecting portion 540b. For example, the belt 540 may have a track shape extending from the first connecting portion 540a to the second connecting portion 540b. As the second connecting portion 540b is coupled to the second housing 220, at least a portion including the first connecting portion 540a of the belt 540 may be linked with the movement of the second driving part 520 with respect to the second housing 220 and move in the second driving part 520. The at least a portion of the belt 540 including the first connecting portion 540a may move in the first direction 261 in the second driving part 520 based on the movement of the second driving part 520 in the first direction 261 with respect to the second housing 220. The at least a portion of the belt 540 including the first connecting portion 540a may move in the second direction 262 in the second driving part 520 based on the movement of the second driving part 520 in the second direction 262 opposite to the first direction 261 with respect to the second housing 220. The first connecting portion 540a may be configured to move the periphery 532a of the second region 532 in the first direction 261 or the second direction 262 opposite to the first direction 261 by moving in the first direction 261 or the second direction 262 opposite to the first direction 261 by the belt 540 driving in the second driving part 520.

According to an embodiment, the periphery 532a of the second region 532 spaced apart from the first region 531 may extend in a direction perpendicular to the first direction 261 or the second direction 262 opposite to the first direction 261, in the electronic device 101.

According to an embodiment, the second driving part 520 may include belts 541 and 542. For example, the second driving part 520 may include a first belt 541 and a second belt 542 faced away the first belt 541. Each of the first belt 541 and the second belt 542 may include the first connecting portion 540a coupled to the periphery of the second region 532 spaced apart from the first region 531 and perpendicular to the first direction 261. Each of the first belt 541 and the second belt 542 may include the second connecting portion 540b coupled to the second housing 220. The second driving part 520 may be configured to transmit a driving force to move the second region 532 in a uniform direction (e.g., the first direction 261 or the second direction 262) to the periphery 532a of the second region 532, by including the belts 541 and 542.

The second driving part 520 is described as including the belts 541 and 542, but the disclosure is not limited in this respect. The second driving part 520 may include a plurality of belts including the belts 541 and 542. The electronic device 101 may be configured to transmit the driving force to move the second region 532 to the periphery 532a of the second region 532 in the uniform direction by including the plurality of belts in the second driving part 520.

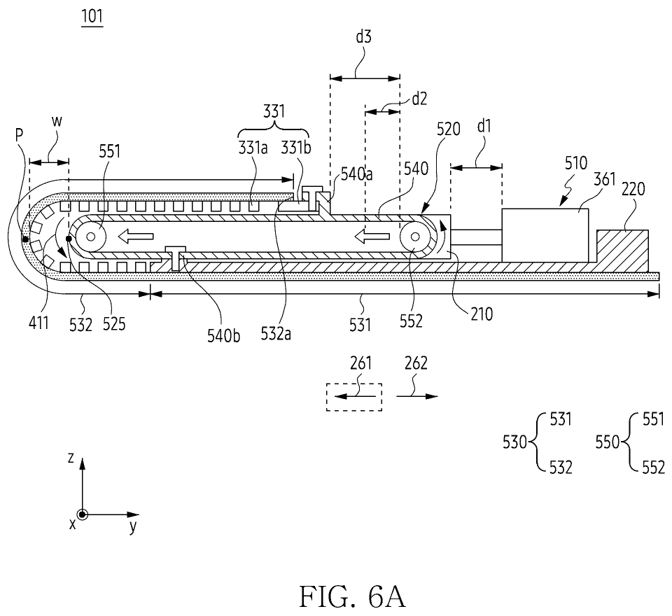

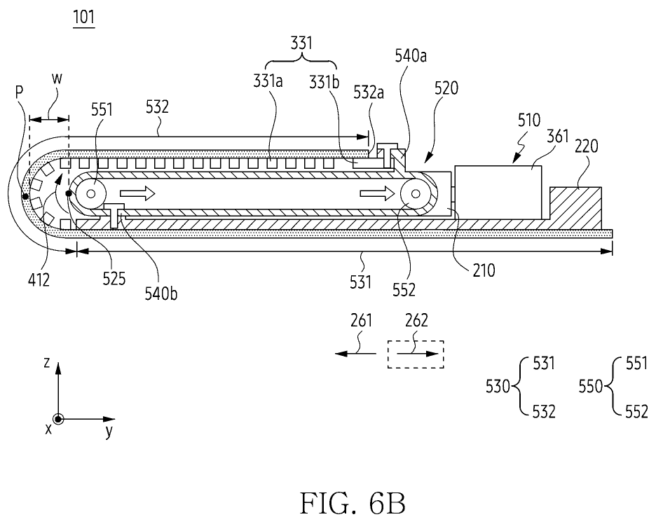

According to an embodiment, the second driving part 520 may include at least one roller 550 arranged with respect to the belt 540. For example, the at least one roller 550 may face a periphery of the belt 540. For example, the at least one roller 550 may be configured such that the belt 540 includes a curvature. For example, the at least one roller 550 may be linked with the belt 540. As the second driving part 520 moves with respect to the second housing 220, the at least one roller 550 may be moved with respect to the second housing 220. The at least one roller 550 may be configured to rotate by the belt 540, by moving with respect to the second housing 220. At least a portion of the belt 540 may be configured to move in the second driving part 520 by rotation of the at least one roller 550. With regard to linking of the belt 540 and the at least one roller 550, it will be described below with reference to FIGS. 6A and 6B.

According to an embodiment, the electronic device 101 may further include the support 331. The support 331 may include a plurality of supporting bars 331a and a supporting plate 331b. The plurality of supporting bars 331a may support the flexible display 530. The supporting plate 331b may support the periphery 532a of the second region 532 perpendicular to the first direction 261 and spaced apart from the first region 531. The first connecting portion 540a of the belt 540 may be attached to the supporting plate 331b.

For example, the plurality of supporting bars 331a may be attached to an inner surface of the flexible display 530 facing the inside of the electronic device 101. For example, each of the plurality of supporting bars 331a may be spaced apart from each other at a specified interval. The plurality of supporting bars 331a may reduce damage to the second region 532 that is deformed according to the electronic device 101 is driven, by supporting the flexible display 530.

For example, the supporting plate 331b may be one bar of the plurality of supporting bars 331a. For example, the supporting plate 331b may be in contact with the second region 532, and the first connecting portion 540a of the belt 540. For example, a portion of the supporting plate 331b may be coupled to a portion of the second region 532 that includes the periphery 532a of the second region 532 spaced apart from the first region 531. A remaining portion of the supporting plate 331b except for the portion of the supporting plate 331b may be coupled to the first connecting portion 540a of the belt 540. The first connecting portion 540a may be configured to move the second region 532 by transmitting a force according to the driving of the belt 540 to the periphery 532a of the second region 532 through the supporting plate 331b.

According to an embodiment, the first driving part 510 may further include a screw 511. The screw 511 may be configured to move the first housing 210 with respect to the second housing 220 by rotating by the motor 361. For example, the screw 511 may be configured to be rotated by the motor 361 of the first driving part 510. The screw 511 may move the first housing 210 in the first direction 261 with respect to the second housing 220 by rotating in a third rotational direction 501 by the motor 361. The screw 511 may move the first housing 210 in the second direction 262 opposite to the first direction 261 with respect to the second housing 220, by rotating in a fourth rotational direction 502 opposite to the third rotational direction 501 by the motor 361.

According to an embodiment, the screw 511 may include a conchoid to move the first housing 210 by rotating by driving the motor 361. The first housing 210 may include a screw groove accommodating the conchoid to move along the conchoid that rotates by rotating the screw 511.

According to an embodiment, the screw 511 may extend in a direction parallel to the first direction 261 and the second direction 262 to move the first housing 210 in the first direction 261 or the second direction 262 opposite to the first direction 261 with respect to the second housing 220.

According to an embodiment, the first driving part 510 may further include a first bracket 512 in which the screw 511 is disposed. The first bracket 512 may guide the second driving part 520. The second driving part 520 may further include a second bracket 522 in which at least one roller 550 is disposed. The second bracket 522 may be configured to move in the first direction 261 or the second direction 262 opposite to the first direction 261 with respect to the first bracket 512 by rotation of the screw 511.

For example, the first bracket 512 may include a space to accommodate the screw 511. For example, the first bracket 512 may provide a space for the movement of the second bracket 522 that is moved by the rotation of the screw 511. By providing the space, the first bracket 512 may guide a movement of the first bracket 512 in the first direction 261 by rotation of the screw 511 in the third direction 501 and a movement of the first bracket 512 in the second direction 262 opposite to the first direction 261 by rotation of the screw 511 in the fourth direction 502 opposite to the third direction 501.

For example, the second bracket 522 may be configured to be moved with respect to the first bracket 512 by the rotation of the screw 511 by being in contact with the screw 511. Since the second bracket 522 is coupled to the first housing 210, the screw 511 may move the second housing 220 to which the second bracket 522 is coupled with respect to the second housing 220 to which the first bracket 512 is coupled. The screw 511 may be configured to move the at least one roller 550 included in the second bracket 522 with respect to the second housing 220 by moving the second bracket 522 with respect to the second housing 220.

According to an embodiment, the first driving part 510 may further include a guide member 513 coupled to the first bracket 512 independently of the movement of the second bracket 522. The guide member 513 may extend in a direction parallel to the first direction 261 and the second direction 262 opposite to the first direction 261 to guide the movement of the second bracket 522. For example, the screw 511 and the guide member 513 may extend in the direction parallel to the first direction 261 and the second direction 262 opposite to the first direction in the first bracket 512. The guide member 513 may penetrate at least a portion of the second bracket 522. The guide member 513 may guide the second bracket 522 that moves according to the rotation of the screw 511, to move in the first direction 261 or the second direction 262 opposite to the first direction.

According to an embodiment, the first bracket 512 may be a portion of the second housing 220. The first bracket 512 may be integrally formed with the second housing 220. According to an embodiment, the second bracket 522 may be a portion of the first housing 210. The second bracket 522 may be integrally formed with the first housing 210.

According to the above-mentioned embodiment, the electronic device 101 may be configured such that the second region 532 of the flexible display 530 is exposed to the outside or disposed in the electronic device 101 according to the movement of the first housing 210, by including the first driving part 510 configured to move the first housing 210 with respect to the second housing 220. The electronic device 101 may be configured to transmit a force to move the second region 532 to the periphery 532a of the second region 532 by including the second driving part 520 configured to move along the first housing 210 by the first driving part 510. The second driving part 520 may increase a movement distance of the second region 532, by including the belt 540 to move the periphery 532a of the second region 532 in accordance with the movement of the second driving part 520, and the at least one roller 550 to move the belt 540 linked with the belt 540. The belt 540 may reduce damage to the second region 532 that is deformed according to driving of the electronic device 101, by including the first connecting portion 540a configured to transmit a force according to an operation of the first driving part 510 and/or the second driving part 520, to the periphery 532a of the second region 532.

FIGS. 6A and 6B are partial cross-sectional views of an example electronic device according to various embodiments.

Referring to FIGS. 6A and 6B, an electronic device 101 may include a first housing 210, a second housing 220, a flexible display 530 (e.g., the display 230 of FIG. 2A), a first driving part (driver) 510 (e.g., the driving part 360 of FIG. 3B), and a second driving part (driver) 520. The flexible display 530 may include a first region 531 and a second region 532. The first driving part 510 may include a motor 361. The second driving part 520 may include a belt 540 and at least one roller 550.

According to an embodiment, the at least one roller 550 may move with respect to the second housing 220 by the second driving part 520 that moves with respect to the second housing 220. The second driving part 520 may be moved with respect to the second housing 220 by the first driving part 510. As the at least one roller 550 moves in a first direction 261 with respect to the second housing 220, the at least one roller 550 may be configured to rotate in a first rotational direction 411. As the at least one roller 550 is moved in a second direction 262 opposite to the first direction 261 with respect to the second housing 220, the at least one roller 550 may be configured to rotate in a second rotational direction 412 opposite to the first rotational direction 411. The at least one roller 550 may move along the second driving part 520 that moves in the first direction 261 or the second direction 262 opposite to the first direction 261 with respect to the second housing 220.

For example, the at least one roller 550 may contact an inner surface of the belt 540. A portion of the belt 540 in contact with the at least one roller 550 may have a curvature by the at least one roller 550. As the second driving part 520 moves by driving of the first driving part 510, the at least one roller 550 may move in a direction in which the second driving part 520 moves. The at least one roller 550 may be rotated through friction with the belt 540, in a case of moving along the second driving part 520.

For example, referring to FIG. 6A, in a case that the second driving part 520 is moved in the first direction 261 with respect to the second housing 220 by the first driving part 510, the at least one roller 550 may be moved in the first direction 261 along the second driving part 520. The at least one roller 550 may be rotated in the first rotational direction 411 through the friction with the belt 540 in contact with the at least one roller 550 based on the movement of the at least one roller 550 in the first direction 261. The portion of the belt 540 in contact with the at least one roller 550 may be rotated in the first rotational direction 411 by the rotation of the at least one roller 550 in the first rotational direction 411. As the portion of the belt 540 in contact with the at least one roller 550 is rotated in the first rotational direction 411, a first connecting portion 540a of the belt 540 extending from the portion of the belt 540 may be moved in the first direction 261.

For example, when referring to FIG. 6B, in a case that the second driving part 520 is moved in the second direction 262 opposite to the first direction 261 with respect to the second housing 220 by the first driving part 510, the at least one roller 550 may be moved in the second direction 262 along the second driving part 520. The at least one roller 550 may be rotated in the second rotational direction 412 opposite to the first rotational direction 411 through the friction with the belt 540 in contact with the at least one roller 550 based on the movement of the at least one roller 550 in the second direction 262. The portion of the belt 540 in contact with the at least one roller 550 may be rotated in the second rotational direction 412 by the rotation of the at least one roller 550 in the second rotational direction 412. As the portion of the belt 540 in contact with the at least one roller 550 is rotated in the second rotational direction 412, the first connecting portion 540a of the belt 540 may be moved in the second direction 262.

Referring again to FIGS. 6A and 6B, the at least one roller 550 may contact the belt 540. The at least one roller 550 may include a first roller 551 and a second roller 552 to maintain tension of the belt 540. The second roller 552 may face the first roller 551 and may be close to the motor 361. For example, the first roller 551 and the second roller 552 may contact the inner surface of the belt 540. The first roller 551 and the second roller 552 may be spaced apart from each other at a specified interval in the second driving part 520. The first roller 551 may be spaced apart in the first direction 261 with respect to the second roller 552. The second roller 552 may be spaced apart in the second direction 262 opposite to the first direction 261 with respect to the first roller 511. The first roller 551 may face away the second roller 552.

For example, portions of the belt 540 in contact with the rollers 551 and 552 may include a curvature. Remaining portions of the belt 540 between the portions of the belt 540 in contact with the rollers 551 and 552 may extend in a direction parallel to the first direction 261 or the second direction 262 opposite to the first direction 261, that is a movement direction of the second driving part 520 including the rollers 551 and 552. As the rollers 551 and 552 are rotated based on the driving of the first driving part 510, portions including the curvature of the belt 540 in contact with the rollers 551 and 552 may vary. The portions of the belt 540 in contact with the rollers 551 and 552 may rotate in the first rotational direction 411 or the second rotational direction 412 opposite to the first rotational direction 411 by rotation of the rollers 551 and 552. The first connecting portion 540a of the belt 540 may move in the first direction 261 or the second direction 262 opposite to the first direction by the rotation of the portions by the rotation of the rollers 551 and 552.

According to an embodiment, the first connecting portion 540a of the belt 540 may be moved by rotation of the at least one roller 550 with respect to the second connecting portion 540b coupled to the second housing 220 independently of the rotation of the at least one roller 550. The first connecting portion 540a may be configured to move in the first direction 261 by the rotation of the at least one roller 550 in the first rotational direction 411 with respect to the second connecting portion 540b. The first connecting portion 540a may be configured to move in the second direction 262 opposite to the first direction 261 by the rotation of the at least one roller 550 in the second rotational direction 412 opposite to the first rotational direction 411 with respect to the second connecting portion 540b.

For example, since the second housing 220 is coupled to the second connecting portion 540b of the belt 540, the second housing 220 may fasten a position of the second connecting portion 540b, independently of a movement of the first housing 210 that is moved by the first driving part 510 with respect to the second housing 220. The at least one roller 550 may be moved by the second driving part 520, which moves along the first housing 210. The portion of the belt 540 may be rotated by the at least one roller 550. The first connecting portion 540a extending from the portion of the belt 540 may be moved in the first direction 261 or the second direction 262 opposite to the first direction 261 with respect to the second connecting portion 540b, by the rotation of the portion of the belt 540.

For example, when referring to FIG. 6A, as the at least one roller 550 rotates in the first rotational direction based on the driving of the first driving part 510, the portion of the belt 540 may be rotated in the first rotational direction 411. Another portion of the belt 540 extending from the portion of the belt 540 and including the first connecting portion 540a may extend in the first direction 261 or the second direction 262 opposite to the first direction 261. The other portion of the belt 540 including the first connecting portion 540a may be moved in the first direction 261 by the rotation of the portion of the belt 540 in the first rotational direction 411. The first connecting portion 540a may be configured to move the second region 532 of the flexible display 530 in the first direction 261 by moving in the first direction 261 along the other portion of the belt 540.

For example, when referring to FIG. 6B, as the at least one roller 550 is rotated in the second rotational direction 412 opposite to the first rotational direction 411 based on the driving of the first driving part 510, the portion of the belt 540 may be rotated in the second rotational direction 412. The other portion of the belt 540 extending from the portion of the belt 540 and including the first connecting portion 540a may extend in the first direction 261 or the second direction 262 opposite to the first direction 261. The other portion of the belt 540 including the first connecting portion 540a may be moved in the second direction 262 by the rotation of the portion of the belt 540 in the second rotational direction 412. The first connecting portion 540a may be configured to move the second region 532 of the flexible display 530 in the second direction 262 by moving in the second direction 262 along the other portion of the belt 540.

Referring again to FIGS. 6A and 6B, the second region 532 of the flexible display 530 may be visually exposed to the outside of the second housing 220 based on a movement of the first connecting portion 540a in the first direction 261. The second region 532 may be rolled into the second housing 220 based on a movement of the first connecting portion 540a in the second direction 262 opposite to the first direction 261.

For example, when referring to FIG. 6A, a periphery 532a of the second region 532 spaced apart from the first region 531 may be coupled to the first connecting portion 540a of the belt 540 through a supporting plate 331b of a support 331. The first connecting portion 540a may be moved in the first direction 261 with respect to the second housing 220, by the second driving part 520 that is moved in the first direction 261 with respect to the second housing 220 by the first driving part 510, and the at least one roller 550 that is rotated in the first rotational direction 411 based on the movement of the second driving part 520 in the first direction 261. The periphery 532a of the second region 532 may be moved in the first direction 261 by the first connecting portion 540a that moves in the first direction 261. The second region 532 may be visually exposed to the outside based on the movement of the second driving part 520 in the first direction 261 and the movement of the periphery 532a in the first direction 261.

For example, when referring to FIG. 6B, the periphery 532a of the second region 532 spaced apart from the first region 531 may be coupled to the first connecting portion 540a of the belt 540 through the supporting plate 331b of the support 331. The first connecting portion 540a may be moved in the second direction 262 with respect to the second housing 220 by the second driving part 520 that is moved in the second direction 262 opposite to the first direction 261 with respect to the second housing 220 by the first driving part 510, and the at least one roller 550 that is rotated in the second rotational direction 412 opposite to the first rotational direction 411 based on the movement of the second driving part 520 in the second direction 262. The periphery 532a of the second region 532 may be moved in the second direction 262 by the first connecting portion 540a that moves in the second direction 262. The second region 532 may be rolled into the second housing 220 based on the movement of the second driving part 520 in the second direction 262 and the movement of the periphery 532a in the second direction 262.

Referring again to FIGS. 6A and 6B, a distance d3 that the first connecting portion 540a is moved with respect to the second connecting portion 540b by the movement of the second driving part may be longer than a distance dl that the second driving part 520 moves with respect to the second housing 220. For example, since the second connecting portion 540b of the belt 540 is coupled to the second housing 220, the distance d3 that the first connecting portion 540a moves with respect to the second connecting portion 540b along the second driving part 520 may include the distance d1 that the second driving part 520 moves with respect to the second housing 220. The distance d3 that the first connecting portion 540a moves with respect to the second connecting portion 540b may include a distance that the portion of the belt 540 including the first connecting portion 540a is moved by the rotation of the at least one roller 550. The electronic device 101 may be configured such that the distance d3 in which the first connecting portion 540a moves with respect to the second connecting portion 540b by the second driving part 520 is longer than the distance d1 in which the second driving part 520 moves with respect to the second housing 220, thereby increasing a movement distance of the second region 532 according to driving of the electronic device 101.

According to an embodiment, the distance d3 in which the periphery 532a of the second region 532 perpendicular to the first direction 261 and spaced apart from the first region 531 moves by the second driving part 520 may correspond to a sum of the distance d1 in which the second driving part 520 moves with respect to the second housing 220 and a distance d2 in which the second connecting portion 540b moves by the rotation of the at least one roller 550. For example, the periphery 532a of the second region 532 perpendicular to the first direction 261 and spaced apart from the first region 531 may be moved by the first connecting portion 540a that is moved with respect to the second housing 220 based on the driving of the first driving part 510. The distance d3 in which the first connecting portion 540a moves with respect to the second housing 220 may correspond to the distance d3 in which the periphery 532a of the second region 532 moves with respect to the second housing 220. The distance d3 in which the first connecting portion 540a moves with respect to the second housing 220 may include the distance d2 in which a portion including the first connecting portion 540a of the belt 540 is moved by the rotation of the at least one roller 550. Since the second connecting portion 540b of the belt 540 is coupled to the second housing 220, the distance d3 in which the first connecting portion 540a moves with respect to the second housing 220 may include the distance d1 in which the second driving part 520 including the belt 540 moves with respect to the second housing 220. The distance d3 in which the first connecting portion 540a moves with respect to the second housing 220 may correspond to the sum of the distance d1 and the distance d2 based on the second driving part 520 that is moved with respect to the second housing 220 by the first driving part 510.

According to an embodiment, when viewed from above, the second driving part 520 may further include the periphery 525 overlapping the second region 532 of the flexible display 530. A distance between the periphery 525 of the second driving part 520 and a position p of the second region 532 spaced apart in the first direction 261 toward which the periphery 525 of the second driving part 520 faces may be maintained at a specified interval w, independently of the rotation of the at least one roller 550. For example, the periphery 525 of the second driving part 520 may be a portion of the belt 540. For example, the periphery 525 of the second driving part may be a portion of a second bracket (e.g., the second bracket 522 of FIG. 5A) in which the at least one roller 550 of the second driving part 520 is disposed. For example, the position p of the second region 532 spaced apart from the periphery 525 of the second driving part 520 in the first direction 261 toward the periphery 525 of the second driving part 520 may be changed while the second region 532 is exposed to the outside or the second region 532 is rolled into the second housing 220. The distance d1 that the position p of the second region 532 is moved in the first direction 261 or the second direction 262 opposite to the first direction by the first driving part 510 and the second driving part 520 may correspond to the distance d1 that the second driving part 520 is moved with respect to the second housing 220 by the first driving part 510. Since the distance d1 that the position p of the second region 532 moves corresponds to the distance d1 that the second driving part 520 moves with respect to the second housing 220, the interval w between the periphery 525 of the second driving part 520 and the position p of the second region 532 may be maintained independently of an operation of the first driving part 510 and the second driving part 520. For example, the interval w may correspond to a thickness of the support 331 between the periphery 525 of the second driving part 520 and the position p of the second region 532. As the interval w is maintained independently of the rotation of the at least one roller 550 of the second driving part 520, the electronic device 101 may reduce damage to the second region 532 due to the movement of the second driving part 520.

According to the above-described embodiment, the electronic device 101 may be configured such that the second region 532 of the flexible display 530 may be exposed to the outside or disposed in the electronic device 101 in accordance with the movement of the first housing 210, by including the first driving part 510 configured to move the first housing 210 with respect to the second housing 220. The electronic device 101 may be configured to transmit a force to move the second region 532 to the periphery 532a of the second region 532 by including the second driving part 520 configured to move along the first housing 210 by the first driving part 510. The second driving part 520 may increase the movement distance of the second region 532, by including the belt 540 to move the periphery 532a of the second region 532 in accordance with the movement of the second driving part 520, and the at least one roller 550 to move the belt 540 linked with the belt 540. The belt 540 may reduce damage to the second region 532 that is deformed according to the driving of the electronic device 101 by including the first connecting portion 540a configured to transmit a force according to the operation of the first driving part 510 and/or the second driving part 520 to the periphery 532a of the second region 532.

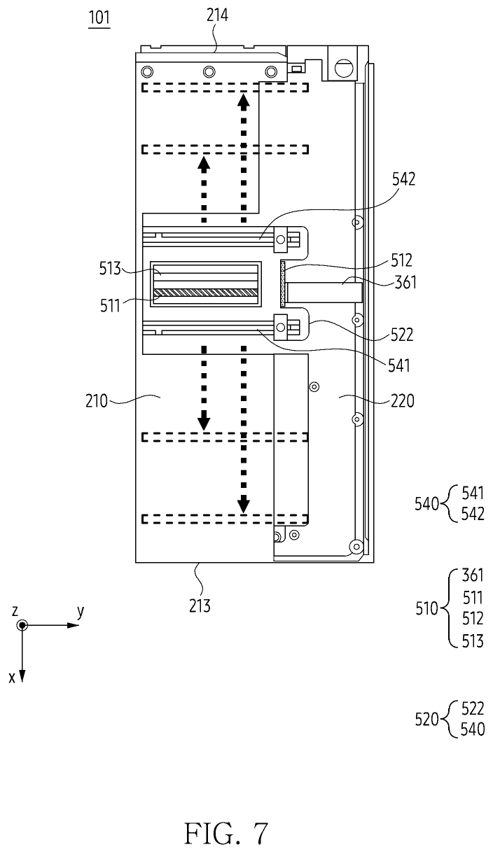

FIG. 7 illustrates a portion of an example electronic device according to various embodiments.

Referring to FIG. 7, an electronic device 101 may include a first housing 210, a second housing 220, a first driving part (driver) 510 (e.g., the driving part 360 of FIG. 3B), and a second driving part (driver) 520. The first driving part 510 may include a motor 361, a screw 511, a first bracket 512, and a guide member 513. The second driving part 520 may include a belt 540.

According to an embodiment, the belt 540 may be disposed between a periphery of the first housing 210 and the first driving part 510 that is parallel to a first direction 261 parallel to a y-axis and a second direction 262 opposite to the first direction 261. For example, the electronic device 101 may include a first belt 541 and a second belt 542. The belts 541 and 542 may be parallel to the screw 511 and the guide member 513 of the first driving part 510. The first belt 541 may be disposed between the first driving part 510 and a first periphery 213 of the first housing 210. The second belt 542 may be disposed between the first driving part 510 and a second periphery 214 of the first housing 210 facing the first periphery 213. As the belt 540 is disposed between the first driving part 510 and the periphery of the second housing parallel to the first direction 261 and the second direction 262 opposite to the first direction 261 of the first housing 210, the electronic device 101 may provide a space for internal components (e.g., the battery 189 of FIG. 1) of the electronic device 101 between the first driving part 510 and the belt 540. As the belt 540 is disposed between the periphery of the first housing 210 and the first driving part 510, the electronic device 101 may provide a space for the internal components of the electronic device 101 between the periphery of the first housing 210 and the belt 540.

According to an embodiment, the belt 540 may be disposed along the periphery of the first housing 210. For example, the first belt 541 may be disposed along the first periphery 213 of the first housing 210. The second belt 542 may be disposed along the second periphery 214 of the first housing 210 facing the first periphery 213 of the first housing 210. As the belt 540 is disposed along the periphery of the first housing 210, the electronic device 101 may provide the space for the internal components of the electronic device 101 between the belt 540 and the first driving part 510.

According to the above-described embodiment, the electronic device 101 may provide the space for the internal components of the electronic device 101 by including the belt 540 disposed parallel to the peripheries 213 and 214 of the first housing 210 in the electronic device 101.

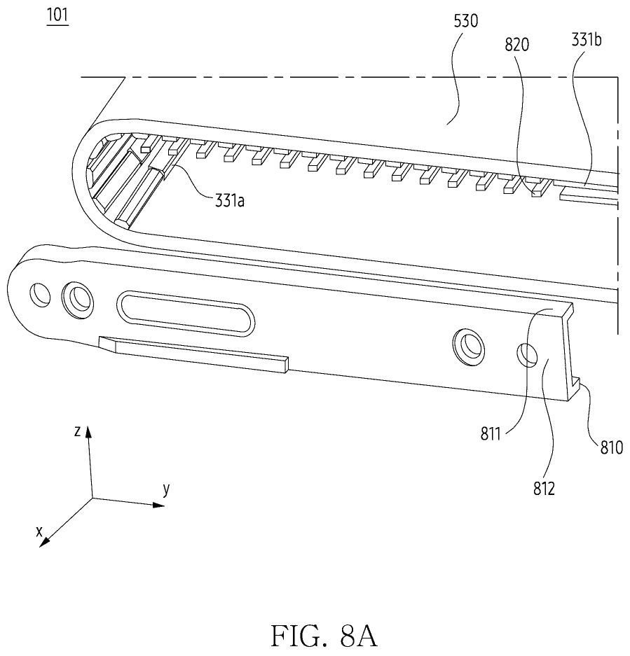

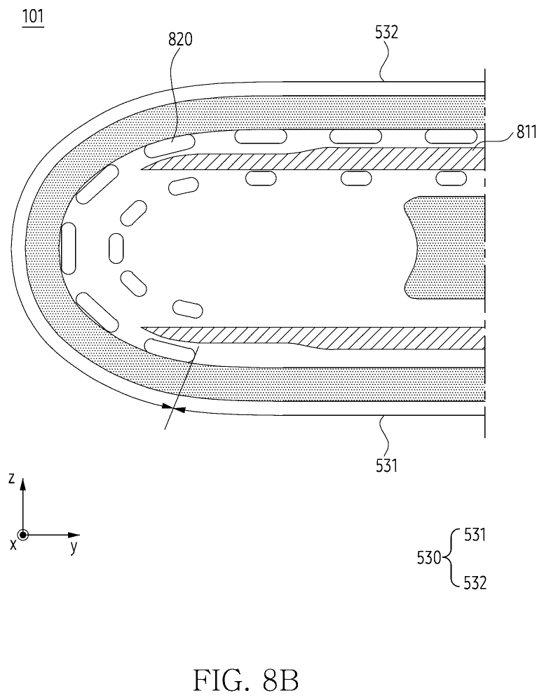

FIG. 8A illustrates a portion of an example electronic device according to various embodiments. FIG. 8B is a partial cross-sectional view of an example electronic device according to various embodiments.

Referring to FIGS. 8A and 8B, an electronic device 101 may include a flexible display 530 and a support 331. The flexible display 530 may include a first region 531 and a second region 532. The support 331 may include a plurality of supporting bars 331a and a supporting plate 331b.

According to an embodiment, the electronic device 101 may further include a guide rail 810 (e.g., the rails 313a of FIG. 3A). The guide rail 810 may guide a movement of a second region 532 of the flexible display 530. The support 331 may further include a guide structure 820 disposed at both ends of each of the plurality of supporting bars 331a. The guide structure 820 may partially surround the guide rail 810. For example, the guide rail 810 may partially surround an internal space of the electronic device 101 by partially contacting the guide structure 820. For example, the guide structure 820 may be moved along the second region 532 that moves according to driving of the electronic device 101. The guide rail 810 may be moved in a first direction 261 or a second direction 262 opposite to the first direction along the guide structure 820 that is moved by the movement of the second region 532. According to an embodiment, the guide rail 810 and the guide structure 820 may be engaged with each other. As the electronic device 101 includes the guide rail 810 and the guide structure 820 engaged with each other, separation of the second region 532 according to the driving of the electronic device 101 may be reduced.

According to an embodiment, the guide rail 810 may include a first portion 811 in contact with the guide structure 820 of the support 331 and a second portion 812 extending from the first portion 811. The first portion 811 may extend in a direction parallel to the first direction 261 and the second direction 262 opposite to the first direction 261. For example, the first portion 811 of the guide rail 810 may be covered by the guide structure 820. The first portion 811 may extend in the first direction 261 and the second direction 262 opposite to the first direction 261 in the guide structure 820. The second portion 812 of the guide rail 810 extending from the first portion 811 may partially surround the internal space of the electronic device 101. As the first portion 811 of the guide rail 810 extends in the direction parallel to the first direction 261 and the second direction 262, the first portion 811 may not include a curved surface. Since the first portion 811 does not include the curved surface, the electronic device 101 may reduce damage to the second region 532 by the guide rail 810 that moves as the electronic device 101 is driven.

According to the above-described embodiment, the electronic device 101 may reduce the separation of the second region 532 of the flexible display 530 according to the driving of the electronic device 101 by including the guide rail 810 and the guide structure 820 partially surrounding the guide rail 810. The first portion 811 in contact with the guide structure 820 of the guide rail 810 may reduce damage to the second region 532 by the guide rail 810 that moves as the electronic device 101 is driven, by not including the curved surface.

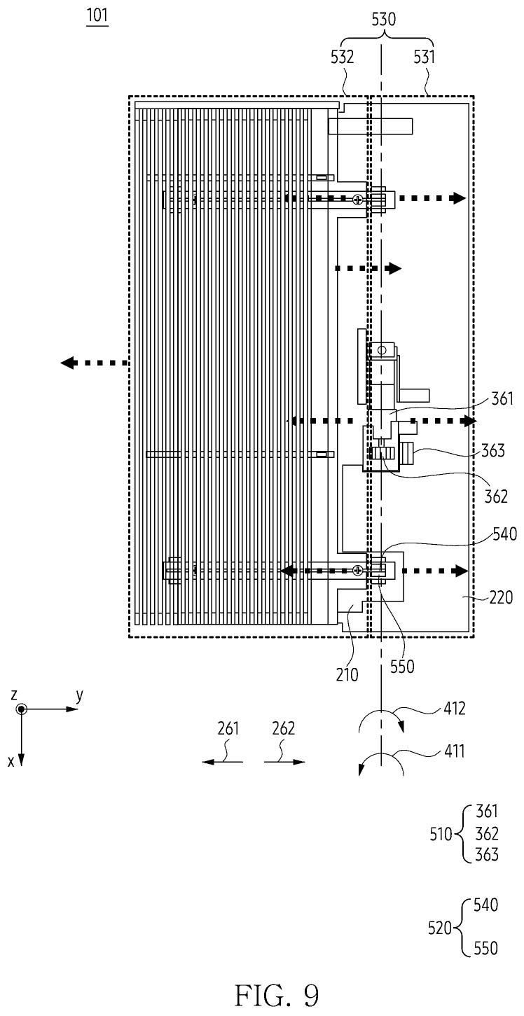

FIG. 9 illustrates a portion of an example electronic device according to various embodiments.

Referring to FIG. 9, an electronic device 101 may include a first housing 210, a second housing 220, a flexible display 530 (e.g., the display 230 of FIG. 2A), a first driving part (driver) 510 (e.g., the driving part 360 of FIG. 3B), and a second driving part (driver) 520. The flexible display 530 may include a first region 531 and a second region 532. The first driving part 510 may include a motor 361. The second driving part 520 may include a belt 540 and at least one roller 550.

According to an embodiment, the first driving part 510 may further include a pinion gear 362 and a rack gear 363. The pinion gear 362 may be configured to rotate in a first rotational direction 411 or a second rotational direction 412 opposite to the first rotational direction 411 by the motor 361. The rack gear 363 may be engaged with the pinion gear 362. The rack gear 363 may be configured to move the first housing 210 with respect to the second housing 220 by rotation of the pinion gear 362. The rack gear 363 may be configured to move the first housing 210 in a second direction 262 opposite to the first direction 261 by the rotation of the pinion gear 362 in the first rotational direction 411. The rack gear 363 may be configured to move the first housing 210 in the first direction 261 by the rotation of the pinion gear 362 in the second rotational direction 412 opposite to the first rotational direction 411.

For example, the rack gear 363 may extend in the first direction 261 and the second direction 262 opposite to the first direction 261. The rack gear 363 may be engaged with the pinion gear 362 rotated by the motor 361 and may transmit a force to the first housing 210.

For example, the pinion gear 362 may be rotated in the first rotational direction 411 by a motor. The pinion gear 362 may be configured to move the rack gear 363 engaged with the pinion gear 362 in the second direction 262 opposite to the first direction 261 with respect to the second housing 220, by rotating in the first rotational direction 411. The rack gear 363 may transmit the force to the first housing 210 by moving in the second direction 262 so that the first housing 210 moves in the second direction 262 with respect to the second housing 220.

For example, the pinion gear 362 may be rotated in the second rotational direction 412 opposite to the first rotational direction 411 by the motor. The pinion gear 362 may be configured to move the rack gear 363 engaged with the pinion gear 362 in the first direction 261 with respect to the second housing 220 by rotating in the second rotational direction 412. The rack gear 363 may transmit the force to the first housing 210 by moving in the first direction 261 so that the first housing 210 moves in the first direction 261 with respect to the second housing 220.

According to an embodiment, the second driving part 520 may be configured to move the second region 532 of the flexible display 530 by moving in the first direction 261 or the second direction 262 opposite to the first direction 261 with respect to the second housing 220 by the first driving part 510.

For example, the pinion gear 362 that is rotated in the first rotational direction 411 by the motor 361 of the first driving part 510 may move the rack gear 363 engaged with the pinion gear 362 in the second direction 262 opposite to the first direction 261. The first housing 210 may be moved in the second direction 262 with respect to the second housing 220 by the movement of the rack gear 363 in the second direction 262. Along the movement of the first housing 210 in the second direction 262, the second driving part 520 may be moved in the second direction 262. The at least one roller 550 in the second driving part 520 may be linked with the belt 540 in the second driving part 520 and rotate in the second rotational direction 412 opposite to the first rotational direction 411, based on the movement in the second direction 262 of the second driving part 520. The belt 540 may be configured to move the second region 532 in the second direction 262 with respect to the second housing 220, by the second driving part 520 moved in the second direction 262 with respect to the second housing 220 and the at least one roller 550 rotated in the second rotational direction 412.

For example, the pinion gear 362 that is rotated in the second rotational direction 412 opposite to the first rotational direction 411 by the motor 361 of the first driving part 510 may move the rack gear 363 engaged with the pinion gear 362 in the first direction 261. The first housing 210 may be moved in the first direction 261 with respect to the second housing 220, by the movement of the rack gear 363 in the first direction 261. Along the movement of the first housing 210 in the first direction 261, the second driving part 520 may be moved in the first direction 261. The at least one roller 550 in the second driving part 520 may be linked with the belt 540 in the second driving part 520 and rotate in the first rotational direction 411, based on the movement in the first direction 261 of the second driving part 520. The belt 540 may be configured to move the second region 532 in the first direction 261 with respect to the second housing 220, by the second driving part 520 moving in the first direction 261 with respect to the second housing 220 and the at least one roller 550 rotating in the first rotational direction 411.

According to the above-described embodiment, the electronic device 101 may transmit a driving force to the first housing 210 for moving the first housing 210 and the second driving part 520 with respect to the second housing 220, by including the pinion gear 362 and the rack gear 363 included in the first driving part 510. The second driving part 520 may increase a movement distance of the second region 532 by including the belt 540 that moves the second region 532 in accordance with the movement of the second driving part 520, and the at least one roller 550 that moves the belt 540 linked with the belt 540, thereby increasing the moving distance of the second region 532. The belt 540 may reduce damage to the second region 532 that is deformed in accordance with the driving of the electronic device 101, by being configured to transmit a force according to an operation of the first driving part 510 and/or the second driving part 520 to the second region 532.

According to an embodiment, an electronic device (e.g., the electronic device 101 of FIG. 1) may include a first housing (e.g., the first housing 210 of FIG. 2A), a second housing (e.g., the second housing 220 of FIG. 2A) movably coupled to the first housing, and a display (e.g., the display module 160 of FIG. 1, the display 230 of FIG. 2A, and the flexible display 530 of FIG. 5B) including a first region (e.g., the first region 230a of FIG. 2A, the first region 531 of FIG. 5B), disposed on the second housing, and a second region (e.g., the second region 230b of FIG. 2C, the second region 532 of FIG. 5B) extending from the first region of the display. The electronic device may further include a first driving part (driver) (e.g., the first driving part 510 of FIG. 5A), including a motor (e.g., the motor 361 of FIG. 3A), configured to move the first housing in a first direction (e.g., the first direction 261 of FIG. 2A) or a second direction (e.g., the second direction 262 of FIG. 2A) opposite to the first direction with respect to the second housing, and coupled to the second housing and a second driving part (driver) (e.g., the second driving part 520 of FIG. 5A), coupled to the first housing to move with respect to the second housing in accordance with a movement of the first housing to move with respect to the second housing, and configured to move the second region of the display in the first direction or the second direction opposite to the first direction. The second driving part may include a belt (e.g., the belt 540 of FIG. 5A) including a first connecting portion (e.g., the first connecting portion 540a of FIG. 5B) coupled to a periphery (e.g., the periphery 532a of FIG. 5B) of the second region of the display spaced apart from the first region of the display, and a second connecting portion (e.g., the second connecting portion 540b of FIG. 5B) coupled to the second housing and at least one roller (e.g., the at least one belt 550 of FIG. 5A) arranged with respect to the belt. The at least one roller may be configured to rotate with respect to the second housing by the second driving part configured to move with respect to the first housing. The first connecting portion of the belt may be configured to move with respect to the second connecting portion of the belt by a rotation of the at least one roller, the second connecting portion being coupled to the second housing independently of the rotation of the at least one roller. According to an embodiment, the electronic device may increase a movement distance of the second region in the first direction or the second direction opposite to the first direction by including the second driving part moved by the first driving part and configured to move the second region. The second driving part may increase a movement distance of the belt by including the at least one roller rotated based on a movement of the second driving part by the first driving part. The belt may be configured to move the second region in the first direction or the second direction opposite to the first direction with respect to the second housing by including the first connecting portion coupled to a periphery of the second region. The belt may increase the movement distance of the belt by including the second connecting portion coupled to the second housing independently of the movement of the first housing. The belt may reduce damage to the second region that is deformed according to driving of the electronic device by including the first connecting portion that transmits a driving force to move the second region to the periphery of the second region. The above-mentioned embodiment may have various effects including the above-mentioned effects.

According to an embodiment, the at least one roller may be configured to rotate in a first rotational direction (e.g., the first rotational direction 411 of FIG. 4A) in accordance with the movement of the at least one roller in the first direction with respect to the second housing, or rotate in a second rotational direction (e.g., the second rotational direction 412 of FIG. 4B) opposite to the first rotational direction in accordance with the movement of the at least one roller in the second direction opposite to the first direction with respect to the second housing. The first connecting portion of the belt may be configured to move in the first direction with respect to the second connecting portion of the belt by the rotation of the at least one roller in the first rotational direction, or move in the second direction opposite to the first direction with respect to the second connecting portion of the belt by the rotation of the at least one roller in the second rotational direction opposite to the first rotational direction. The second region of the display may be configured to be exposed to an outside of the second housing based on the movement of the first connecting portion of the belt in the first direction, or be rolled into the second housing based on the movement of the first connecting portion of the belt in the second direction opposite to the first direction. According to an embodiment, the electronic device may provide various user experiences to the user of the electronic device by including the display including the second region exposed to the outside or rolled into the inside of the electronic device in accordance with the movement of the first connecting portion. The example embodiment may have various effects including the above-mentioned effects.

According to an embodiment, the first driving part may further include a screw (e.g., the screw 511 of FIG. 5A) configured to move the first housing with respect to the second housing, by being rotated by the motor. According to an embodiment, the first driving part may be configured to efficiently transmit a driving force according to driving of the motor to the first housing by including the screw. The embodiment may have various effects including the above-mentioned effects.

According to an embodiment, the first driving part may further include a first bracket (e.g., the first bracket 512 of FIG. 5A) in which the screw is disposed, to guide the second driving part. The second driving part may further include a second bracket (e.g., the second bracket 522 of FIG. 5A) in which the at least one roller is disposed, the second bracket configured to move with respect to the first bracket in the first direction or the second direction opposite to the first direction by the rotation of the screw. According to an embodiment, the electronic device may guide the movement of the first housing and the second driving part that moves in accordance with the first housing in the first direction or in the second direction opposite to the first direction, and reduce separation of the first housing and the second driving part by including the first bracket and the second bracket. The embodiment may have various effects including the above-mentioned effects.

According to an embodiment, the first driving part may further include a guide member (e.g., the guide member 513 of FIG. 5A), coupled to the first bracket independently of a movement of the second bracket, extending from a direction parallel to the first direction and the second direction opposite to the first direction to guide the movement of the second bracket. According to an embodiment, the first driving part may guide the movement of the second driving part including the second bracket in the first direction or in the second direction opposite to the first direction, and reduce the separation of the second driving part by including the guide member. The embodiment may have various effects including the above-mentioned effects.

According to an embodiment, the first driving part may include a pinion gear (e.g., the pinion gear 362 of FIG. 3A) configured to rotate in the first rotational direction or the second rotational direction opposite to the first rotational direction by the motor. The first driving part may further include a rack gear (e.g., the rack gear 363 of FIG. 3A), engaged with the pinion gear, configured to move the first housing in the second direction by the rotation of the pinion gear in the first rotational direction, or move the first housing in the first direction by the rotation of the pinion gear in the second rotational direction opposite to the first rotational direction. According to the above-mentioned embodiment, the first driving part may be configured to efficiently transmit a driving force to the first housing to move the first housing and the second driving part that moves in accordance with the first housing, with respect to the second housing, by including the pinion gear and the rack gear. The embodiment may have various effects including the above-mentioned effects.

According to an embodiment, the at least one roller may be contacted with the belt. The at least one roller may include a first roller (e.g., the first roller 551 of FIG. 6A) to maintain tension of the belt, and a second roller (e.g., the second roller 552 of FIG. 6A), facing the first roller, close to the motor. According to an embodiment, the at least one roller may be configured to be rotated through a frictional force with the belt as the second driving part moves by being in contact with the belt. The at least one roller may be configured to maintain the tension of the belt by including the first roller and the second roller. The belt may be configured to efficiently move the second region of the display by the first roller and the second roller that moves based on the movement of the second driving part by maintaining the tension of the belt by the first roller and the second roller. The embodiment may have various effects including the above-mentioned effects.

According to an embodiment, a distance (e.g., the distance d3 of FIG. 6A) that the first connecting portion moves with respect to the second connecting portion by the second driving part may be longer than a distance (e.g., the distance d1 of FIG. 6A) that the second driving part moves with respect to the second housing. According to an embodiment, since the distance that the second driving part moves with respect to the second housing is shorter than the distance that the first connecting portion moves with respect to the second connecting portion by the second driving part, the second driving part may increase a distance to move the second region in the first direction or the second direction opposite to the first direction. The embodiment may have various effects including the above-mentioned effects.

According to an embodiment, a support may further include a plurality of supporting bars (e.g., the plurality of supporting bars 331a of FIG. 5B) that support the display, and a supporting plate (e.g., the supporting plate 331b of FIG. 5B) that supports the periphery of the second region of the display. The first connecting portion of the belt may be attached to the supporting plate. According to an embodiment, the electronic device may reduce damage to the second region that is deformed according to driving of the electronic device, by including the support. The support may be configured to transmit a driving force to move the second region in the first direction or in the second direction opposite to the first direction, from the first connecting portion of the belt to the periphery of the second region by including the supporting plate. The embodiment may have various effects including the above-mentioned effects.

According to an embodiment, the electronic device may further include a guide rail (e.g., the rails 313a of FIG. 3A and the guide rail 810 of FIG. 8A) to guide the display. The support may further include a guide structure (e.g., the guide structure 820 of FIG. 8A), disposed at both ends of each of the plurality of supporting bars, partially surrounding the rail. According to an embodiment, the electronic device may guide the movement of the second region of the display that moves according to the driving of the electronic device by including the guide rail 810 and the guide structure 820. The embodiment may have various effects including the above-mentioned effects.

According to an embodiment, the guide rail may include a first portion (e.g., the first portion 811 of FIG. 8A) contacted with the guide structure, and a second portion (e.g., the second portion 812 of FIG. 8A) extending from the first portion. The first portion of the guide rail may extend in a direction parallel to the first direction and the second direction opposite to the first direction. According to an embodiment, as the first portion in contact with the guide structure is extended in a direction parallel to the first direction and the second direction opposite to the first direction, the guide rail may reduce damage to the second region by the guide rail that moves according to the driving of the electronic device. The embodiment may have various effects including the above-mentioned effects.

According to an embodiment, a distance (e.g., the distance d3 of FIG. 6A) that the periphery of the second region moves by the second driving part may correspond to a sum of a distance (e.g., the distance d1 of FIG. 6A) that the second driving part moves with respect to the second housing and a distance (e.g., the distance d2 of FIG. 6A) that the second connecting portion of the belt moves by the rotation of the at least one roller. According to an embodiment, as the distance that the periphery of the second region moves by the second driving part corresponds to the sum of the distance that the second driving part moves with respect to the second housing, and the distance that the second connecting portion moves by the rotation of at least one roller, the second driving part may increase the movement distance of the second region moved by the second driving part. The embodiment may have various effects including the above-mentioned effects.

According to an embodiment, the second driving part may further include a periphery (e.g., the periphery 525 of FIG. 6A), when viewed from above, overlapping the second region of the display. A distance between the periphery of the second driving part and a position (e.g., the position p of FIG. 6A) of the second region spaced apart from the periphery of the second driving part in the first direction toward which the periphery of the second driving part faces, may be maintained at a specified interval (e.g., the interval w of FIG. 6A) independently of the rotation of the roller. According to an embodiment, as a distance between the periphery of the second driving part and the position of the second region spaced apart in the first direction toward the periphery of the second driving part is maintained at the specified interval, the electronic device may reduce damage to the second region by the first housing and the second driving part that moves according to the driving of the electronic device. The embodiment may have various effects including the above-mentioned effects.

According to an embodiment, the belt may be disposed between a periphery (e.g., the first periphery 213 and the second periphery 214 of FIG. 7) of the first housing parallel to the first direction and the second direction opposite to the first direction, and the first driving part. According to an embodiment, the second driving part may provide a space for internal components of the electronic device to the electronic device by being configured to be disposed between the periphery of the first housing and the first driving part. The embodiment may have various effects including the above-mentioned effects.

According to an embodiment, the belt may be disposed along the periphery of the first housing. According to an embodiment, the second driving part may provide the electronic device with a space for internal components of the electronic device, by being configured such that the belt is disposed along the periphery of the first housing to the electronic device. The embodiment may have various effects including the above-mentioned effects.

According to an embodiment, an electronic device may include a first housing, a second housing movably coupled to the first housing, and a display including a first region disposed on the second housing, and a second region extending from the first region of the display. The electronic device may further include a first driving part (driver), including a motor, configured to move the first housing in a first direction or a second direction opposite to the first direction with respect to the second housing, and coupled to the second housing, and a second driving part (driver), coupled to the first housing to move with respect to the second housing in accordance with a movement of the first housing to move with respect to the second housing, and configured to move the second region of the display in the first direction or the second direction opposite to the first direction. The second driving part may include a belt including a first connecting portion (connector) coupled to a periphery of the second region of the display spaced apart from the first region of the display, and a second connecting portion (connector) coupled to the second housing and at least one roller in contact with the belt. The at least one roller may be configured to rotate in a first rotational direction in accordance with the movement of the at least one roller in the first direction with respect to the second housing, or rotate in a second rotational direction opposite to the first rotational direction in accordance with the movement of the at least one roller in the second direction opposite to the first direction with respect to the second housing by the second driving part moving with respect to the second housing. The first connecting portion of the belt may be configured to move in the first direction with respect to the second connecting portion of the belt by a rotation of the at least one roller in the first rotational direction or move in the second direction opposite to the first direction with respect to the second connecting portion of the belt by the rotation of the at least one roller in the second rotational direction opposite to the first rotational direction, the second connecting portion being coupled to the second housing independently of the rotation of the at least one roller. The second region of the display may be configured to be exposed to an outside of the second housing based on the movement of the first connecting portion of the belt in the first direction or be rolled into the second housing based on the movement of the first connecting portion of the belt in the second direction opposite to the first direction. According to an embodiment, the electronic device may increase a movement distance of the second region in the first direction or the second direction opposite to the first direction by including the second driving part moved by the first driving part and configured to move the second region. The second driving part may increase a movement distance of the belt by including the at least one roller rotated based on a movement of the second driving part by the first driving part. The belt may be configured to move the second region in the first direction or the second direction opposite to the first direction with respect to the second housing by including the first connecting portion coupled to a periphery of the second region. The belt may increase the movement distance of the belt by including the second connecting portion coupled to the second housing independently of the movement of the first housing. The belt may reduce damage to the second region that is deformed according to driving of the electronic device by including the first connecting portion that transmits a driving force to move the second region to the periphery of the second region. The at least one roller may be configured to be rotated through a frictional force with the belt as the second driving part moves by being in contact with the belt. The electronic device may provide various user experience to the user of the electronic device by including the display including the second region exposed to the outside or rolled into the inside of the electronic device according to the movement of the first connecting portion. The embodiment may have various effects including the above-mentioned effects.

According to an embodiment, the first driving part may further include a screw configured to move the first housing with respect to the second housing, by being rotated by the motor. According to an embodiment, the first driving part may be configured to efficiently transmit a driving force according to driving of the motor to the first housing by including the screw. The embodiment may have various effects including the above-mentioned effects.

According to an embodiment, the first driving part may further include a pinion gear configured to rotate in the first rotational direction or the second rotational direction opposite to the first rotational direction by the motor. The first driving part may further include a rack gear, engaged with the pinion gear, configured to move the first housing in the second direction by the rotation of the pinion gear in the first rotational direction, or move the first housing in the first direction by the rotation of the pinion gear in the second rotational direction opposite to the first rotational direction. According to an embodiment, the first driving part may be configured to efficiently transmit a driving force to the first housing to move the first housing and the second driving part that moves in accordance with the first housing, by including the pinion gear and the rack gear. The embodiment may have various effects including the above-mentioned effects.

According to an embodiment, a distance that the first connecting portion is moved with respect to the second connecting portion by the second driving part may be longer than a distance that the second driving part is moved with respect to the second housing. According to an embodiment, since the distance that the second driving part moves with respect to the second housing is shorter than the distance that the first connecting portion moves with respect to the second connecting portion by the second driving part, the second driving part may increase a distance to move the second region in the first direction or the second direction opposite to the first direction. The embodiment may have various effects including the above-mentioned effects.

According to an embodiment, a support may further include a plurality of supporting bars that support the display, and a supporting plate that supports the periphery of the second region of the display. The first connecting portion of the belt may be attached to the supporting plate. According to an embodiment, the electronic device may reduce damage to the second region that is deformed according to driving of the electronic device, by including the support. The support may be configured to transmit a driving force to move the second region in the first direction or in the second direction opposite to the first direction, from the first connecting portion of the belt to the periphery of the second region by including the supporting plate. The embodiment may have various effects including the above-mentioned effects.

According to an embodiment, a distance that the second region is moved by the second driving part may correspond to the sum of the distance that the second driving part moves with respect to the second housing and the distance that the second connecting portion is moved by the rotation of the at least one roller. According to an embodiment, as the distance that the periphery of the second region moves by the second driving part corresponds to the sum of the distance that the second driving part moves with respect to the second housing, and the distance that the second connecting portion moves by the rotation of at least one roller, the second driving part may increase the movement distance of the second region moved by the second driving part. The embodiment may have various effects including the above-mentioned effects.

According to an embodiment, the second driving part may further include a periphery, when viewed from above, overlapping the second region of the display. A distance between the periphery of the second driving part and a position of the second region spaced apart from the periphery of the second driving part in the first direction toward which the periphery of the second driving part faces, may be maintained at a specified interval independently of the rotation of the roller. According to an embodiment, as a distance between the periphery of the second driving part and the position of the second region spaced apart in the first direction toward the periphery of the second driving part may be maintained at the specified interval, the electronic device may reduce damage to the second region by the first housing and the second driving part that are moved according to the driving of the electronic device. The embodiment may have various effects including the above-mentioned effects.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” “at least one of A, B, or C,” and “at least one of A, B, and/or C” may include any one of or all possible combinations of the items enumerated together in a corresponding one of the phrases. As used herein, such terms as “1st” and “2nd,” or “first” and “second” may be used to simply distinguish a corresponding component from another, and do not limit the components in other aspect (e.g., importance or order). It is to be understood that if an element (e.g., a first element) is referred to, with or without the term “operatively” or “communicatively”, as “coupled with,” or “connected with” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium, where the term “non-transitory” simply refers to the storage medium being a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

The disclosure has been described with reference to the embodiments. It would be appreciated by those skilled in the art that changes may be made to these embodiments without departing from the principles and spirit of the disclosure. Therefore, the disclosed embodiments are provided for the purpose of describing the disclosure and the disclosure should not be construed as being limited to only the embodiments set forth herein. The scope of the disclosure is defined by the claims as opposed to by the above-mentioned descriptions, and it should be understood that disclosure includes all differences made within the equivalent scope. It will also be understood that any of the embodiment(s) described herein may be used in conjunction with any other embodiment(s) described herein.

What is claimed is:

1. An electronic device comprising:
a first housing;
a second housing movably coupled to the first housing;
a display including:
a first region disposed on the second housing, and
a second region extending from the first region;
a first driver, including a motor, configured to move the first housing in a first direction or a second direction opposite to the first direction with respect to the second housing, and coupled to the second housing; and
a second driver, coupled to the first housing to move with respect to the second housing in accordance with a movement of the first housing to move with respect to the second housing, configured to move the second region of the display in the first direction or the second direction,
wherein the second driver includes:
a belt including a first connector coupled to a periphery of the second region of the display spaced apart from the first region of the display, and a second connector coupled to the second housing, and
at least one roller arranged with respect to the belt,
wherein the at least one roller is configured to rotate with respect to the second housing by the second driver configured to move with respect to the second housing, and
wherein the first connector is configured to move with respect to the second connector by a rotation of the at least one roller, the second connector being coupled to the second housing independently of the rotation of the at least one roller.

2. The electronic device of claim 1,
wherein the at least one roller is configured to:
rotate in a first rotational direction in accordance with the movement of the at least one roller in the first direction with respect to the second housing, or
rotate in a second rotational direction opposite to the first rotational direction in accordance with the movement of the at least one roller in the second direction opposite to the first direction with respect to the second housing,
wherein the first connector is configured to:
move in the first direction with respect to the second connector by the rotation of the at least one roller in the first rotational direction, or
move in the second direction opposite to the first direction with respect to the second connector by the rotation of the at least one roller in the second rotational direction opposite to the first rotational direction, and
wherein the second region of the display is configured to:
be exposed to an outside of the second housing based on the movement of the first connector in the first direction, or
be rolled into the second housing based on the movement of the first connector in the second direction opposite to the first direction.

3. The electronic device of claim 1,
wherein the first driver further includes a screw configured to move the first housing with respect to the second housing, by being rotated by the motor.

4. The electronic device of claim 3,
wherein the first driver includes a first bracket in which the screw is disposed, to guide the second driver, and
wherein the second driver further includes a second bracket in which the at least one roller is disposed, the second bracket configured to move with respect to the first bracket in the first direction or the second direction opposite to the first direction by the rotation of the screw.

5. The electronic device of claim 1,
wherein the first driver further includes a guide member, coupled to the first bracket independently of a movement of the second bracket, extending from a direction parallel to the first direction and the second direction opposite to the first direction to guide the movement of the second bracket.

6. The electronic device of claim 1,
wherein the first driver includes:
a pinion gear configured to rotate in a first rotational direction or a second rotational direction opposite to the first rotational direction by the motor,
a rack gear, engaged with the pinion gear, configured to:
move the first housing in the second direction by the rotation of the pinion gear in the first rotational direction, or
move the first housing in the first direction by the rotation of the pinion gear in the second rotational direction.

7. The electronic device of claim 1,
wherein the at least one roller contacts the belt and includes:
a first roller to maintain tension of the belt, and
a second roller, facing the first roller, close to the motor.

8. The electronic device of claim 1,
wherein a distance that the first connector moves with respect to the second connector by the second driver is longer than a distance that the second driver moves with respect to the second housing.

9. The electronic device of claim 1, further comprising a support including:
a plurality of supporting bars configured to support the display, and
a supporting plate configured to support the periphery of the second region of the display,
wherein the first connector is attached to the supporting plate.

10. The electronic device of claim 9, further comprising a guide rail configured to guide the movement of the second region of the display,
wherein the support further includes a guide structure, disposed at both ends of each of the plurality of supporting bars, partially surrounding the guide rail.

11. The electronic device of claim 10,
wherein the guide rail includes:
a first portion contacted with the guide structure, and
a second portion extending from the first portion, and
wherein the first portion of the guide rail extends in a direction parallel to the first direction and the second direction.

12. The electronic device of claim 9,
wherein a distance that the periphery of the second region moves by the second driver corresponds to a sum of a distance that the second driver moves with respect to the second housing and a distance that the second connector moves by the rotation of the at least one roller.

13. The electronic device of claim 1,
wherein the second driver further includes a periphery, when viewed from above, overlapping the second region of the display, and
a distance between the periphery of the second driver and a position of the second region spaced apart from the periphery of the second driver in the first direction toward which the periphery of the second driver faces, is maintained at a specified interval independently of the rotation of the at least one roller.

14. The electronic device of claim 1,
wherein the belt is disposed between a periphery of the first housing parallel to the first direction and the second direction and the first driver.

15. The electronic device of claim 14,
wherein the belt is disposed along the periphery of the first housing.

16. An electronic device comprising:
a first housing;
a second housing coupled to the first housing;
a flexible display including:
a first region disposed on the second housing, and
a second region extending from the first region;
a first driver, including a motor, configured to move the first housing in a first direction or a second direction opposite to the first direction with respect to the second housing, and coupled to the second housing; and
a second driver, coupled to the first housing to move with respect to the second housing in accordance with a movement of the first housing to move with respect to the second housing, configured to move the second region of the flexible display in the first direction or the second direction,
wherein the second driver includes:
a belt including a first connector coupled to a periphery of the second region of the flexible display spaced apart from the first region of the flexible display, and a second connector coupled to the second housing, and
at least one roller contacted with the belt,
wherein the at least one roller is configured to, by the movement of the movement of the second driver with respect to the second housing:
rotate in a first rotational direction in accordance with the movement of the at least one roller in the first direction with respect to the second housing, or
rotate in a second rotational direction opposite to the first rotational direction in accordance with the movement of the at least one roller in the second direction,
wherein the first connector is configured to:
move in the first direction with respect to the second connector by the rotation of the at least one roller in the first rotational direction, or
move in the second direction opposite to the first direction with respect to the second connector by the rotation of the at least one roller in the second rotational direction, and
wherein the second region of the flexible display is configured to:
be exposed to an outside of the second housing based on the movement of the first connector in the first direction, or
be rolled into the second housing based on the movement of the first connector in the second direction.

17. The electronic device of claim 16,
wherein the first driver includes a screw configured to move the first housing with respect to the second housing, by being rotated by the motor.

18. The electronic device of claim 16,
wherein the first driver includes:
a pinion gear configured to rotate in the first rotational direction or the second rotational direction by the motor,
a rack gear, engaged with the pinion gear, configured to:
move the first housing in the second direction by the rotation of the pinion gear in the first rotational direction, or
move the first housing in the first direction by the rotation of the pinion gear in the second rotational direction.

19. The electronic device of claim 16,
wherein a distance that the first connector moves with respect to the second connector by the second driver is longer than a distance that the second driver moves with respect to the second housing.

20. The electronic device of claim 16, further comprising a support including:
a plurality of supporting bars configured to support the flexible display, and
a supporting plate configured to support the periphery of the second region of the flexible display,
wherein the first connector is attached to the supporting plate.
